(19) United States
(12) Patent Application Publication
(10) Pub. No.: US 2011/0316560 A1
(43) Pub. Date: Dec. 29, 2011

(54) REMOTE SENSOR DEVICE

(76) Inventors: John Francis Gregg, Oxford (GB); Alexy Davison Karenowska, Oxford (GB)

(21) Appl. No.: 13/144,880

(22) PCT Filed: Jan. 18, 2010
(86) PCT No.: PCT/GB2010/000065

§ 371 Date: Sep. 13, 2011

(30) Foreign Application Priority Data
Jan. 16, 2009 (GB) 0900744.4

(51) Int. Cl. G01R 27/28

(52) U.S. Cl. 324/617

(57) ABSTRACT

A self-oscillating remote sensor device includes a delay-line sensor system having at least one delay-line and at least one sensor element. The device also includes an oscillator control circuitry, and a frequency selection impedance connecting the delay-line sensor system and the oscillator control circuitry and presenting an impedance to the delay-line sensor system. The oscillator control circuitry includes an amplifier, a non linear amplitude control element (N-LACE) such as an active device with a negative differential conductance that provides an output whose amplitude has a negative second derivative with respect to an input signal, and a driver. Such a device permits successful interaction between electrical sensors and controlling (driving) electronics over long distances without the problems normally encountered when a delay-line is presented between an electrical sensor and its driver electronics.

### FIELD OF THE INVENTION

This invention relates to a remote sensor device, and in particular to an electrical sensor remotely connected with driver electronics via one or more electrical transmission lines forming a delay-line.

### BACKGROUND OF THE INVENTION

As the control and diagnostic requirements of modern plant, scientific instruments and analytical apparatus become ever more demanding, so too does the requirement for high-performance, high-resolution sensors. Sensor technologies in common usage exploit a wide range of techniques and effects but the majority operate in the electrical domain i.e. the raw sensor signal is an electrical change or signature. Such an electrical sensor signal may arise as a direct result of interaction between an electrical sensor element and a system that is being measured, for example, the location or motion of a metallic component may be sensed by measuring a change in the inductance of an electrically excited coil brought about by its presence in the vicinity of the coil's magnetic field. Alternatively, the signal may be derived from an electrical change that occurs as an indirect consequence of interaction between a sensor element and an arrangement of local control circuitry, for example—an optical sensor may produce a signal that brings about a change in the impedance of a local, coupled electrical system which is itself measured. Whilst techniques for optimizing electrical sensor arrangements in conjunction with local driving and measurement electronics—i.e. driving and measurement electronics that are connected to the sensor element by negligibly short pieces of electrical signal cable—are numerous and accessible, severe difficulties are associated with the realization of systems in which the raw signal from the sensitive element is received by the measurement and control electronics via a length of transmission line that is comparable to, long, or very long in comparison with its wavelength (say, several metres or tens of metres in the case of an RF signal); for example: where there is a requirement to make a measurement in a hostile or high temperature environment remote from the nearest signal processing node of an integrated measurement and control system. The present state-of-the-art in sensor instrumentation is incompatible with sensor systems that necessitate long raw signal paths. This incompatibility presents a significant barrier to successful or enhanced monitoring and control of many high-performance scientific and engineering systems. Thus there is required an improved means to operate electrical sensors in conjunction with long raw-signal transmission cables.

In the following, the term ‘electrical’ is used in the most general sense and encompasses—unless otherwise stated—phenomena related to or connected with any region of the electromagnetic spectrum.

### SUMMARY OF THE INVENTION

Against this background, and in accordance with a first aspect of the present invention, there is provided a remote sensor device as set out in claim 1. Such a device permits successful interaction between electrical sensors and controlling (driving) electronics over long distances without the problems normally encountered when a delay-line is presented between an electrical sensor and its driver electronics.

The invention also extends to a combination of a remote sensor device as set out herein with a first conductive object and, optionally, a second object as well. Further aspects reside in a closed loop arrangement. Other features and advantages of the present invention will be apparent from the appended claims and the following description.

### BRIEF DESCRIPTION OF THE DRAWINGS

FIG. 1 shows a simple delay-line sensor system;

FIG. 2A shows a remote sensor device (RSD) embodying the present invention and including a control circuitry having a Non-Linear Amplitude Control Element (N-LACE) linked to a delay-line sensor system having a delay-line and a sensor element, via a frequency selection impedance;

FIG. 2B shows a block schematic diagram of the functional components of the arrangement of FIG. 2A;

FIG. 3 shows the electrical equivalent circuit of an example of the sensor element of FIG. 2A;

FIG. 4A shows a plot of the magnitude of input impedance as a function of frequency for an example delay-line sensor system;

FIG. 4B shows a plot of the inverse of the magnitude of input impedance as a function of frequency for an example delay-line sensor system;

FIG. 4C shows a magnified view of a part of the plot of FIG. 4A;

FIG. 4D shows a magnified view of a part of the plot of FIG. 4B;

FIGS. 5A and 5B provide a graphical representation of the operating principles of a noise initiated self-oscillating system;

FIG. 6A represents the arrangement of a negative conductance oscillator in terms of effective impedances;

FIG. 6B shows an electrical equivalent circuit for the delay-line sensor system of FIG. 2A;

FIG. 7 shows an electrical equivalent circuit for the RSD arrangement of FIG. 2A;

FIG. 8 shows an alternative electrical equivalent circuit for the RSD arrangement of FIG. 2A, with the N-LACE functionality shown separately from that of the remainder of the control circuitry;

FIG. 9 shows an idealised input-output characteristic for an “optimal Non-Linear Amplitude Control Element” (oN-LACE), an optimized realization of the N-LACE of FIG. 2A;

FIG. 10A shows a symmetrical sinusoidal input signal, and FIGS. 10B-10G show different output signals, for an optimized (oN-LACE) realization of the N-LACE of FIG. 2A;

FIG. 11 shows a single positive half cycle of the input signal of FIG. 10A superimposed upon a single positive half cycle of the output signal of an optimized (oN-LACE) realization of the N-LACE of FIG. 2A;

FIG. 12 shows an asymmetric input signal for the N-LACE of FIG. 2A;

FIG. 13 shows a first asymmetric output signal for an optimized (oN-LACE) realization of the N-LACE of FIG. 2A;

FIG. 14 shows a second asymmetric output signal for an optimized (oN-LACE) realization of the N-LACE of FIG. 2A;

FIG. 15A shows an idealised small and large signal input-output characteristic of an optimized (oN-LACE) realization of the N-LACE of FIG. 2A;

FIGS. 15B-15D show different less optimal input-output characteristics thereof, and FIG. 15E shows the small and large signal input-output characteristics of a non-linear amplitude control element which has undesirable characteristics;

FIG. 16 shows a circuit diagram exemplifying one optimized (oN-LACE) implementation of the N-LACE of FIG. 2A;

FIG. 17 shows a circuit diagram exemplifying a further optimized (oN-LACE) implementation of the N-LACE of FIG. 2A;

FIGS. 18A, 18B and 18C show alternative embodiments of RSDs in accordance with the present invention and including delay-line sensor systems;

FIGS. 19A and 19B show further alternative embodiments of RSDs in accordance with the present invention and including delay-line sensor systems;

FIGS. 20A and 20B show delay-line sensor systems suitable for the RSDs of FIG. 18A;

FIGS. 21A and 21B show delay-line sensor systems suitable for the RSDs of FIGS. 18B and 18C

FIGS. 22A and 22B show delay-line sensor systems suitable for the RSDs of FIGS. 19A and 19B respectively;

FIG. 23 shows one mode-selective feedback configuration of a RSD in accordance with an embodiment of the present invention;

FIG. 24 shows an alternative mode-selective feedback configuration of a RSD in accordance with an embodiment of the present invention;

FIG. 25 shows an equivalent circuit for the delay-line sensor system of the RSD of FIG. 24;

FIG. 26A shows yet an alternative mode-selective feedback configuration of a RSD in accordance with an embodiment of the present invention;

FIG. 26B shows a particular implementation of the feedback configuration of FIG. 26A;

FIGS. 27A-D shows a first set of possible variations to the general feedback configuration of FIG. 26B;

FIGS. 28A-D shows a second set of possible variations to the general feedback configuration of FIG. 26B;

FIGS. 29A and B show a third set of possible variations to the general feedback configuration of FIG. 26B;

FIGS. 30A and B show a first and a second specific implementation of the system of FIGS. 27-29;

FIGS. 31A and B show a third and a fourth specific implementation of the system of FIGS. 27-29;

FIGS. 32A and 32B show a fifth and a sixth specific implementation of the system of FIGS. 27-29;

FIGS. 33A and 33B show a seventh and an eighth specific implementation of the system of FIGS. 27-29;

FIGS. 34A and 34B show a ninth and a tenth specific implementation of the system of FIGS. 27-29;

FIG. 35A shows example characteristics of an arrangement of FIG. 23, and FIG. 35B shows a part of FIG. 35A in close up;

FIG. 36A shows example characteristics of an arrangement of FIG. 24, and FIG. 36B shows a part of FIG. 36A in close up;

FIG. 37 shows a schematic arrangement of a RSD in accordance with another embodiment of the present invention;

FIGS. 38A and 38B show schematic arrangements of RSD components in accordance with still other embodiments of the present invention;

FIG. 39 shows a schematic arrangement of an RSD in accordance with another embodiment of the present invention;

FIG. 40A shows a schematic arrangement of an RSD employing a single controller and frequency selection impedance switchable between multiple delay-line sensor systems; FIG. 40B shows a schematic arrangement of an RSD employing a single controller switchable between multiple delay-line sensor systems with respective multiple frequency selection impedances;

FIG. 41 shows a highly schematic representation of a turbine engine having turbine blades and a turbine casing, with a sensor element of an RSD embodying the present invention mounted for sensing rotation of the turbine blades;

FIG. 42A shows a highly schematic configuration wherein the RSD embodying the present invention forms part of a first closed loop control system for controlling a system parameter; and

FIG. 42B shows a highly schematic configuration wherein the RSD embodying the present invention forms a part of a second closed loop control arrangement.

### DETAILED DESCRIPTION OF A PREFERRED EMBODIMENT

In a most general sense, embodiments of the present invention comprise a remote sensor device (RSD) incorporating a positive feedback electrical delay-line self oscillator. The RSD is formed of (as a minimum) a lumped or distributed-parameter electrical sensor element or elements from which it is desirable to make a measurement, at least one delay-line, and an RSD control circuitry. The or each delay-line carries the raw signal from the sensor element(s) to the RSD control circuitry.

Many possible arrangements of sensor element(s) and delay-line(s) are contemplated in the present context. For generality the combination of the delay-line(s) and sensor element(s) will henceforth be referred to as a ‘delay-line sensor system’. A simple example of a delay-line sensor system possible in the present context is a single length of transmission line, length l, characteristic impedance Z₀(jω) terminated by a sensor element with some complex impedance

Z_{L}(jω)=r+jX(ω). (1)

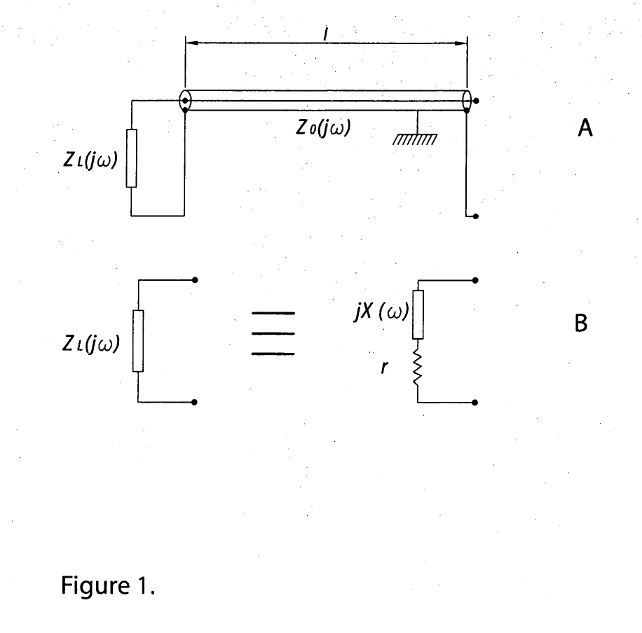

The impedance Z_{L}(jω) varies in response to the stimulus which it is desirable to measure. Such an arrangement is illustrated in FIG. 1A, and the electrical equivalent circuit for the sensor element (as defined by (1)) is shown in FIG. 1B.

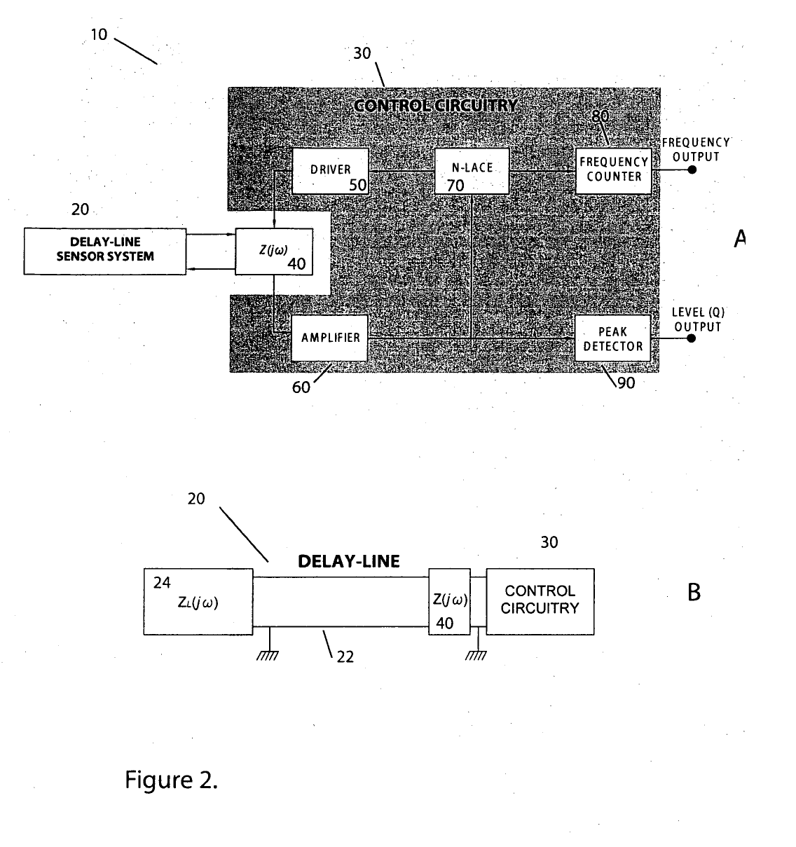

FIG. 2A shows a block diagram illustrating the various functional components of an RSD 10. Although the characteristics and thus detailed design of the functional elements of the RSD 10 are determined according to the particular required functionality (eg, output signal, sensitivity, etc) and engineering constraints (eg the length of the raw signal cables, the sensor characteristics etc, any general RSD 10 embodying the present invention includes four fundamental elements. The first is a sensor element or elements (not shown separately in FIG. 2A) and the second is one or more delay-line(s) (likewise not shown separately in FIG. 2A), which together form a ‘delay-line sensor system’ 20, shown on the left of the diagram. The delay-line sensor system 20 is connected to the other two functional elements of the closed-loop system—a control circuitry 30 and a frequency selection impedance/impedance stage 40 Z(jω).

The control circuitry 30 comprises a driver 50, an amplifier 60 and an amplitude regulator 70, these may or may not be realized by a single electronic circuit but are the minimum functional blocks required for the control circuitry 30. For example, the amplifier 60 may be a non-inverting pre-amplifier realized in discrete or surface mount electronic components and incorporating a low noise, high input impedance operational amplifier. The characteristics of the amplitude regulator 70, together with some examples of circuits providing these characteristics, are set out in further detail below. In general terms, however, it may be noted that the non-linear characteristics of the amplitude regulator 70 might be obtained using a variety of instrumentation techniques: the element may comprise or incorporate an active device with a negative differential conductance by virtue of a physical positive-feedback process. Alternatively, the desired non-linear characteristic may be achieved via a positive-feedback amplifier configuration.

The control circuitry 30 may additionally comprise or incorporate functionality for signal processing/capture: for example, a frequency counter 80 may be included to provide a frequency output and/or a peak detector or demodulator 90 can be employed to provide an output indicative of the level of oscillation of the delay-line sensor system 20.

During a transient start-up period, the RSD 10 commences oscillation. Noise initiated oscillations are received by the amplifier 60, amplified, amplitude regulated by the amplitude regulator 70 and fed back to the delay-line sensor system 20 via the frequency selection impedance 40 Z(jω). Once the start-up period has passed, constant amplitude oscillation of the RSD 10 is established. The combination of the delay-line sensor system 20, the frequency selection impedance 40 Z(jω) and the control circuitry 30 are arranged in such a way as to promote stable, robust oscillation of the closed-loop RSD 10. Particularly, the frequency selection impedance 40 Z(jω) has a certain frequency-dependent magnitude and/or phase shift that provides modal selectivity as explained below.

Thus it will be seen that the RSD 10 comprises a closed-loop positive feedback controlled oscillator, the operating frequency of which is partly or wholly determined by the delay-line sensor system 20. The positive feedback circuitry is arranged in such a way that the resonant system comprising or incorporating the delay-line sensor system 20 is self-excited at one of its resonance frequencies by a driving signal. The frequency of the driving signal (i.e. the operating frequency of the oscillator) is dependent on the imaginary component of the sensor impedance (ℑ{Z_{L}(jω)}=X(ω) in the example of FIG. 1 above) whilst additional loss in the sensor component of the delay-line sensor system 20—i.e. an increase in the real part of the delay-line sensor system 20 impedance ( [symbol] {Z_{L}(jω)}=r in the example above)—manifests itself as a reduction in the quality factor Q of the resonance:

$$Q = 2 π \frac{Energy Stored / cycle}{Energy Dissipated / cycle} \qquad ( 2 )$$

which may be measured as a change in the amplitude (level) of oscillation by, for example, the peak detector 90. Advantageously, the RSD 10 described herein may be designed such that the operating frequency is maximally sensitive to changes in the imaginary part of the sensor impedance (δℑ{Z_{L}(jω)} in the example above) and/or the quality factor Q is maximally sensitive to changes in the real part of the sensor impedance (δ [symbol] {Z_{L}(jω)} in the example above). Thus either or both of two outputs related to the sensor element(s) of the delay-line sensor system 20 are provided by the RSD: a frequency output related to the imaginary part of the sensor impedance and a level (amplitude) output related to the per-cycle loss in the sensor element. Making a measurement with an RSD 10 in accordance with an embodiment of the present invention involves monitoring changes in the values of one or more of these outputs, by for example monitoring the outputs of the frequency counter 80 and/or the peak detector 90.

FIG. 2B is a block schematic diagram of a realization of the RSD 10 in conjunction with the example implementation of the delay-line sensor system 20 described above and illustrated in FIG. 1—a single transmission line 22 terminated by a sensor 24 of impedance Z_{L}(jω). The sensor 24 takes the form of any active or passive electrical element or device (or multiplicity or array thereof) with an electrical impedance that varies in response to some stimulus which it is desirable to detect or measure. The sensor 24 may or may not exhibit one or more self-resonance frequencies. As will be obvious to the skilled reader, in the context of the RSD 10, many sensor elements are possible, for example: a single lumped component e.g. coil or capacitor; a combination of lumped components e.g. an inductor in combination with a capacitor; an array of lumped components e.g. an array of inductive sensors; a distributed-parameter electrical system e.g. one or more lengths of electrical transmission line; a lumped sensor element incorporating a local active or passive circuit e.g. an optical detector in combination with a semiconductor device, or an antenna.

The delay-line or delay-lines employed in the context of embodiments of the present invention comprise a length or lengths of electrical transmission line. Many possible arrangements of delay-line sensor systems 20 comprising a combination of at least one sensor element 24 and at least one electrical delay-line 22 are possible, but in the present context the term “remote” is employed to signify that the raw signal produced by the sensor element 24 has to travel some distance that is at least a substantial fraction of the wavelength of that signal (or the carrier signal upon which the signal appears) to be received by the control circuitry 30. Equivalently, a signal originating from the control circuitry 30 must propagate some distance that is at least a substantial fraction of the wavelength of the signal (or the carrier signal upon which the signal appears) to be received at the sensor 24.

Delay-line sensor systems 20 embodying the present invention are examples of distributed-parameter electrical systems and as such, typically exhibit an input/output phase response that varies continuously with frequency over some finite bandwidth. A given delay-line sensor system 20 has a frequency dependent input impedance Zᵢₙ(jω). The magnitude of the frequency response of the input impedance |Zᵢₙ(jω)| features a series of minima and maxima. Minima correspond to resonance frequencies, maxima to anti-resonance frequencies of the delay-line sensor system 20. The exact form of the input impedance of the delay-line sensor system 20 is dependent on the detail of the arrangement (i.e. multiplicity, type and arrangement of sensor(s) 24 and delay-line(s) 22 incorporated). As will be apparent to the skilled reader, many possible arrangements of delay-line sensor systems 20 may be contemplated. In order to better describe the functioning of the RSD 10 embodying the present invention the example of a delay-line sensor system 20 comprising a single transmission line terminated by a sensor element is considered (i.e., the arrangement illustrated in FIG. 2B). The input impedance Zᵢₙ(jω) of a delay-line sensor system 20 comprising a transmission line, length l, characteristic impedance Z₀(jω), terminated by a complex frequency dependent impedance Z_{L}(jω) is described by

$${Z}_{in} ( jω ) = {Z}_{0} ( jω ) \frac{( {Z}_{L} ( jω ) + {Z}_{0} ( jω ) tanh γ l )}{( {Z}_{0} ( jω ) + {Z}_{L} ( jω ) tanh γ l )} \qquad ( 3 )$$

Here, γ is a propagation coefficient of the form

$$γ = α + j \frac{ω}{{v}_{p}} = α + jβ , \qquad ( 4 )$$

where νₚ is the phase velocity along the transmission line, ω the frequency of excitation and α a loss coefficient. The characteristic impedance of the transmission line) Z₀(jω) is specified in the usual way as

$${Z}_{0} ( j ω ) = \sqrt{\frac{{R}_{0} + j ω {L}_{0}}{{G}_{0} + j ω {C}_{0}}} \qquad ( 5 )$$

where R₀, L₀, G₀ and C₀ are respectively the per-unit length resistance, inductance, shunt conductance and shunt capacitance of the line. In many (though not all) delay-line sensor systems realized in the context the RSD invention, the resistance R₀ and conductance G₀ are sufficiently small as to be negligible and thus the characteristic impedance is approximately

$${Z}_{0} ( j ω ) = {Z}_{0} = \sqrt{\frac{{L}_{0}}{{C}_{0}}} , \qquad ( 6 )$$

which is purely real and frequency independent. Additionally, when these conditions are met, the loss coefficient α in equation (4) is approximately zero (i.e. γ=jβ) and thus (3) may be approximated by

$${Z}_{in} ( j ω ) = {Z}_{0} \frac{( {Z}_{L} ( jω ) + j {Z}_{0} tan β l )}{( {Z}_{0} + j {Z}_{L} ( jω ) tan β l )} . \qquad ( 7 )$$

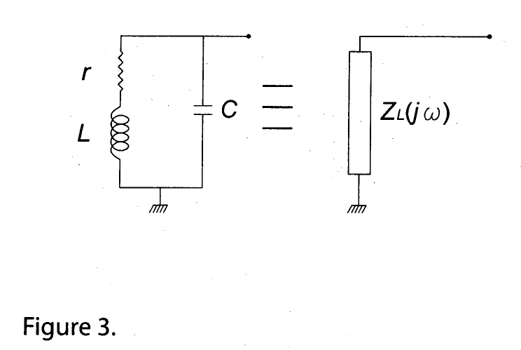

For clarity and brevity in the analysis that follows the approximations (6) and (7) are assumed valid but note that the treatment is easily extended to the case of ‘lossy’ delay-lines. Furthermore, the particular example of a delay-line sensor system 20, comprising a lossless delay-line 22 of length l terminated by an inductive sensor 24 with impedance Z_{L}(jω), is considered. Such an inductive sensor 24 may, for example take the form of a wire-wound coil of inductance L and resistance r. Additionally, associated with such a coil there may be a non-negligible per-winding parasitic capacitance which may be represented by an effective total parasitic capacitance C. Such an arrangement is shown in FIG. 3. An inductive sensor 24 of this type may be employed for example in a system to detect the presence, position and/or characteristics of a moving metallic target.

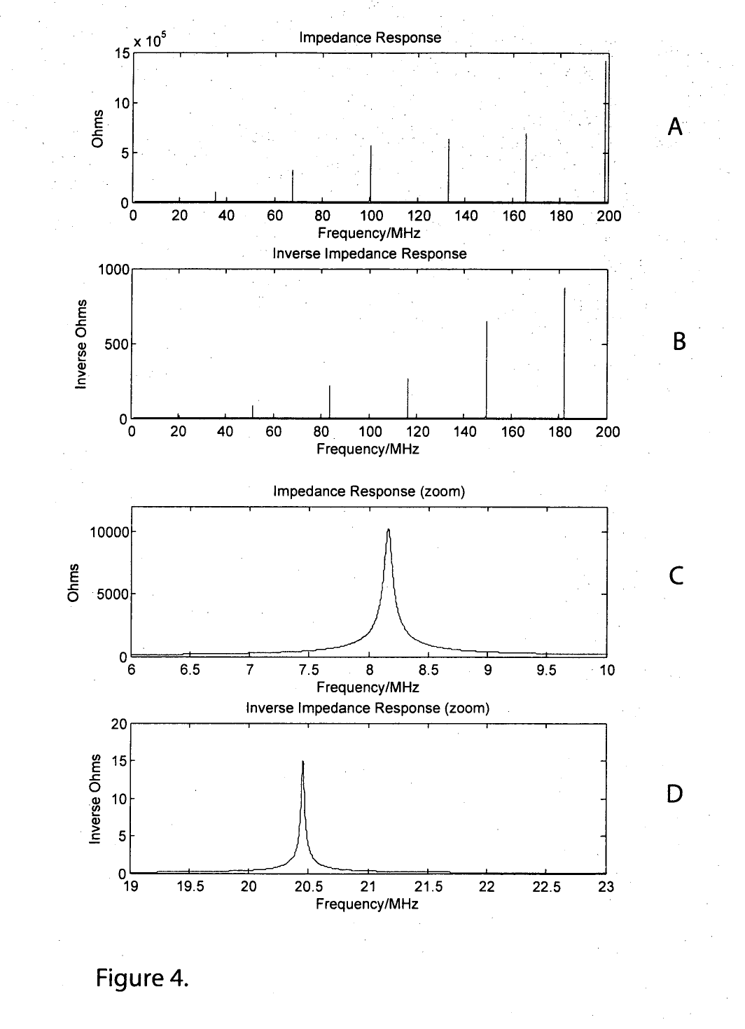

For a delay-line sensor system 20, comprising a lossless delay-line 22 of length l terminated by an inductive sensor 24 with impedance Z_{L}(jω)), and with the parameter values shown in Table 1, FIG. 4A shows a plot of the magnitude of the input impedance |Zᵢₙ(jω)| defined in (7) above, as a function of frequency. The first peak which occurs between 7.5 and 9 MHz (illustrated in the magnified view, FIG. 4C) corresponds to the first anti-resonance frequency of the delay-line sensor system. Subsequent peaks are harmonics. Equation (7) predicts an infinite series of anti-resonance frequencies. In practice, the highest observable harmonic is limited by the real transport properties of the electrical system. FIG. 4B is a plot of the inverse of the magnitude of the input impedance as a function of frequency. The first peak, which occurs between 20 and 21 MHz (illustrated in the magnified view, FIG. 4D) corresponds to the first resonance frequency of the delay-line sensor system, subsequent peaks are harmonics. Equation (7) predicts an infinite series of resonance frequencies. In practice the highest observable harmonic is limited by the real transport properties of the electrical system.

TABLE 1

| Parameter | Symbol | Value |
|---|---|---|
| Delay-line length | l | 3 m |
| Delay-line characteristic impedance | Z₀ | 50 Ω |
| Delay-line phase velocity | νₚ | 2 × 10⁸ ms⁻¹ |
| Resistance of coil | r | 0.5 Ω |
| Parasitic capacitance of coil | C | 2.5 pF |
| Inductance of coil | L | 1 μH |

It is appropriate here to set out in brief the operating principles of an RSD in accordance with embodiments of the present invention, with reference to a general noise-initiated self-oscillating system.

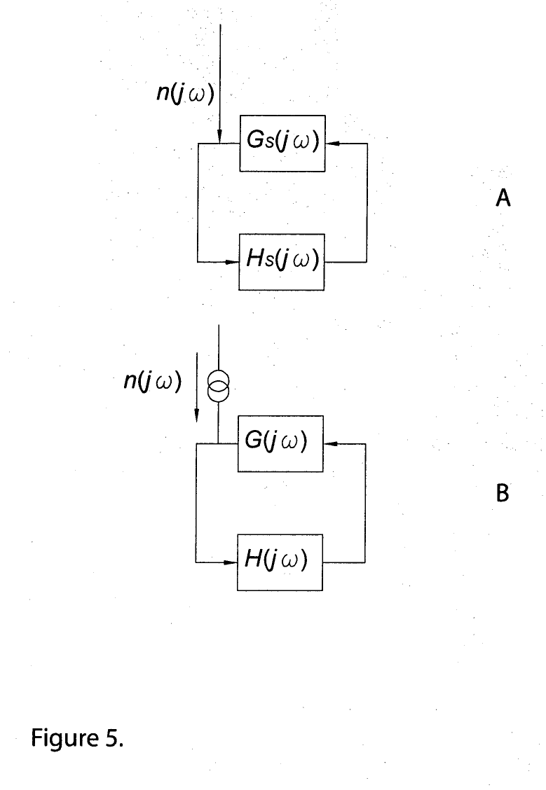

In FIG. 5A G_{S}(jω) is the transfer function of some general system, the magnitude of which has at least one minimum and/or maximum (i.e. at least one resonance and/or anti-resonance frequency). The output of G_{S}(jω) is connected back to its input via the element H_{S}(jω) and n(jω) is a noise source for example, n(jω) may be a white noise source for which n(jω)=n₀. Amplitude stable self-oscillation of such a system at a single frequency ω₀ may be initiated and sustained if the combination of H_{S}(jω) and G_{S}(jω) satisfy the requirements of oscillator start-up and amplitude stabilization (FIG. 5A) and the condition

G_{S}(jω₀)H_{S}(jω₀)=1, (8a)

is satisfied at and only at this frequency. The condition of (8a) implies

|G_{S}(jω₀)H_{S}(jω₀)|=1, (8b)

i.e. unity gain around the closed-loop system, and that the phase of the signal arriving at the input of G_{S}(jω) coincides with the phase of the oscillation sustained in G_{S}(jω) by the control signal's previous trip i.e.

∠G_{S}(jω₀)+∠H_{S}(jω₀)=2πn n=1, 2, 3 (8c)

Accordingly, a noise-initiated, stable, positive-feedback oscillator may be realized operating at some frequency ω₁ in conjunction with a delay-line system, transfer function G(jω) if it can be arranged that some element H(jω) is provided that at and only at the operating frequency ω₁ satisfies the requirements described with reference to the general system of FIG. 5A, i.e.:

|G(jω₁)H(jω₁)|=1, (8d)

∠G(jω₁)+∠H(jω₁)=2πn n=1, 2, 3 (8e)

and meets the requirements of oscillator start-up and amplitude stabilization (FIG. 5B).

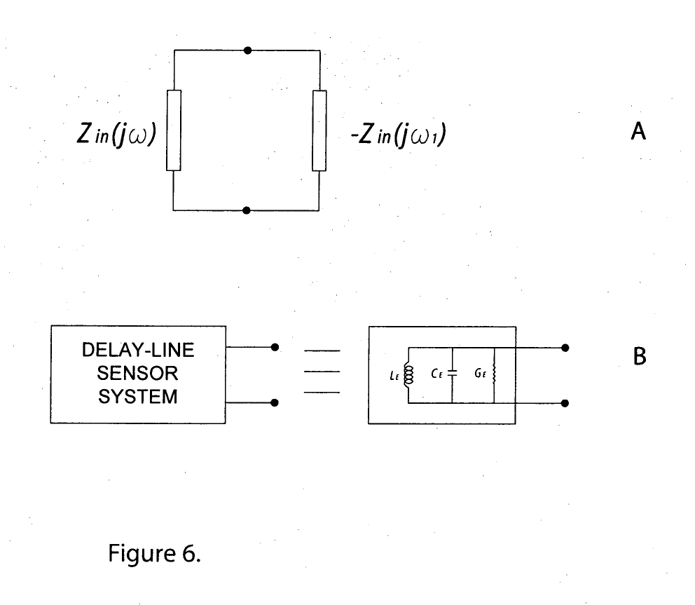

Such a system may be referred to as a ‘negative conductance oscillator’ since the function of H(jω) is equivalent to providing an impedance −Zᵢₙ(jω₁) in the closed loop system (FIG. 6A). This is the basis for the RSD invention, with the combination of the control circuitry and the frequency selection impedance providing H(jω).

In order to discuss the features and characteristics of the RSD invention in the most general sense, it is useful to describe the RSD in terms of a simplified two-terminal ‘equivalent circuit’.

Any delay-line sensor system may be represented by an equivalent two-terminal electrical circuit comprising three shunt elements: an effective inductance L_{E}, capacitance C_{E} and conductance G_{E}. This concept is illustrated in FIG. 6B. The combined impedance of the shunt-connected elements L_{E}, C_{E} and G_{E} being G_{S}. It should be noted that in general, L_{E}, C_{E} and G_{E} will be frequency dependent parameters.

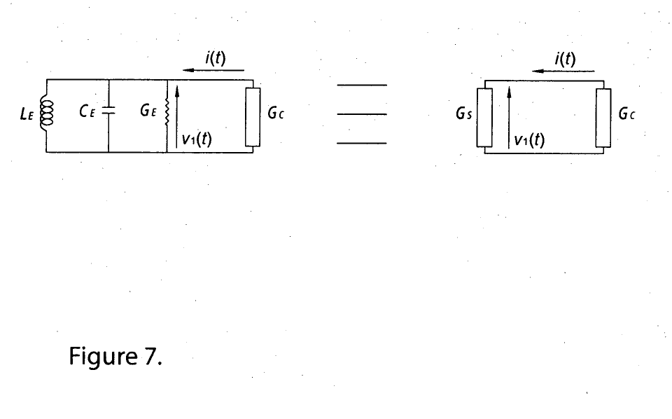

In this representation, the control circuitry 30 incorporating the non-linear amplitude control element (N-LACE) 70 may be modelled by a shunt conductance G_{C} as depicted in FIG. 7, and the operation of the RSD 10 may be described in terms of two time-dependent oscillator control signals: an equivalent current ‘output signal’ i(t) which flows into the combined impedance G_{S}), and originates from G_{C}, and an equivalent voltage ‘input signal’ ν₁(t) which appears across G_{S}. In general, G_{C} will be a complex, frequency dependent conductance with a negative real part and non-linear dependence on ν₁(t).

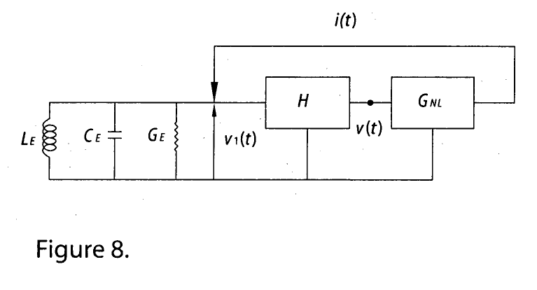

For the purposes of analysis, it is useful to consider functionality of the non-linear amplitude control element (N-LACE) 70 separately from that of the rest of the control circuitry 30. The model of FIG. 8 is equivalent to that of FIG. 7 but here, the control circuitry 30 of the RSD 10 is represented by two complex, frequency dependent elements: G_{NL} representing the N-LACE 70 and H which accounts for the remainder of the functional elements of the control circuitry 30. In this model H is assumed to be entirely linear in ν₁(t) thus, with reference to the figure, the input to the N-LACE 70 ν(t), is a linear function of ν₁(t) whilst the output of the N-LACE 70 i(t) is a non-linear function of ν(t).

The function of the non-linear amplitude control element (N-LACE) 70 is to provide an amplitude regulated feedback signal i(t) to drive the delay-line sensor system 20. In general terms, the N-LACE 70 provides gain and non-linearity. There are several ways in which this can be achieved, although as will be seen, some of these are more preferred than others since they provide for optimized performance of the RSD 10.

The output of the delay-line sensor system 20—ν₁(t) (FIG. 8)—is a continuous periodic energy signal. The signal ν₁(t) has a spectral component s(t) at the operating frequency ω₀ of the RSD 10. The time-period T characteristic of s(t) is given accordingly by:

$$T = \frac{2 π}{{ω}_{0}} . \qquad ( 9 )$$

The signal s(t) is isolated from ν₁(t) (e.g. by filtering and subsequent phase-compensation) so that the signal arriving at the input to the N-LACE 70 is of the form

ν(t)=As(t−τ1), (10)

where A is a constant and τ₁ a time-constant to account for inherent or imposed time delay and/or phase shift in the signal path. The feedback signal generated by the N-LACE 70 in response to ν(t) is of the form:

i(t)=a_{NL}(ν(t−τ₂)). (11)

where

τ₂=τ₁+τ. (12)

and τ is a time delay characteristic of the input-output conversion in the N-LACE 70 which may or may not be frequency dependent. The instantaneous dynamic gain of the N-LACE 70 is defined for any instantaneous signal input ν(t₁):

$${g}_{d} ( {t}_{1} ) = \frac{\partial i ( {t}_{1} + τ )}{\partial v ( {t}_{1} )} . \qquad ( 13 )$$

In the most general implementation of the RSD 10, the function a_{NL}(v(t)) which describes the N-LACE 70 is an arbitrary non-linear function. However, in preferred embodiments of the N-LACE 70, the function a_{NL}(v(t)) has particular advantageous characteristics. From henceforth, a non-linear amplitude control element with such particular advantageous characteristics will be referred to as an optimal non-linear amplitude control element or oN-LACE. The characteristics of such an oN-LACE will now be described.

When at time τ₁ the instantaneous amplitude of the oN-LACE input signal ν(t₁) is between certain preset fixed ‘positive’ and ‘negative’ thresholds the corresponding output i(t₁+τ) of the oN-LACE 70 is approximately equivalent to a linear amplifier with a gain that is—in the most general case—dependent on the polarity of the signal. For a given oN-LACE implementation, the ‘positive’ and ‘negative’ thresholds are respectively

$$+ \frac{{B}_{1}}{{K}_{01}} and - \frac{{B}_{2}}{{K}_{02}}$$

where B₁, B₂ are any real, non-negative integers (so long as in a given realization either B₁ or B₂ is non-zero) and K₀₁ and K₀₂ are real non-zero positive integers equal to the small-signal (SS) dynamic gains for positive and negative ν(t) respectively:

$$\begin{matrix}{g}_{{dSS}^{+}} ( {t}_{1} ) = {K}_{01} = \frac{\partial i ( {t}_{1} + τ )}{\partial v ( {t}_{1} )} {\vert}_{{SS}^{+}} , & ( 14 a ) \\ {g}_{{dSS}^{-}} ( {t}_{1} ) = {K}_{02} = \frac{\partial i ( {t}_{1} + τ )}{\partial v ( {t}_{1} )} {\vert}_{{SS}^{-}} & ( 14 b )\end{matrix}$$

In this signal regime, the output of the oN-LACE 70 is described by

i(t₁+τ)=K₀₁ν(t₁) for sgn{ν(t₁)}=1,

i(t₁+τ)=K₀₂ν(t₁) for sgn{ν(t₁)}=−1. (15)

Note that the relative polarities of the oN-LACE input and output signals are arbitrarily defined. In the most preferred embodiment of the oN-LACE 70, at least one of K₀₁ and K₀₂ is a large, positive, real constant. Equations (14-15) describe the ‘quasi-linear amplification regime’ or ‘small-signal amplification regime’ of the oN-LACE 70.

If at time t₁ the instantaneous amplitude of ν(t₁) is positive and its magnitude equals or exceeds the threshold

$$\frac{{B}_{1}}{{K}_{01}}$$

and/or the instantaneous amplitude of ν(t₁) is negative and its magnitude equals or exceeds the threshold

$$\frac{{B}_{2}}{{K}_{02}} ,$$

the oN-LACE 70 operates in a ‘strongly non-linear’ or ‘large-signal’ regime. In the most preferred embodiment of the oN-LACE 70, the dynamic gain in the large-signal (LS) regime is zero regardless of the polarity of the signal ν(t₁):

$${{g}_{dLS} ( {t}_{1} ) = \frac{\partial i ( {t}_{1} + τ )}{\partial v ( {t}_{1} )} \vert}_{LS} = 0 \qquad ( 16 a )$$

In a general embodiment of the oN-LACE, the large-signal dynamic gain g_{dLS}(t) is approximately zero regardless of the polarity of the signal ν(t₁) i.e:

$${{g}_{dLS} ( {t}_{1} ) = \frac{\partial i ( {t}_{1} + τ )}{\partial v ( {t}_{1} )} \vert}_{LS} \approx 0 \qquad ( 16 b )$$

The most preferred embodiment of the optimal non-linear amplitude control element features a large-signal regime in which the amplitude of the oN-LACE output i(t₁+τ) takes a constant value +B₁ if at time t₁ the instantaneous amplitude of ν(t₁) is positive and a constant value −B₂ if the converse is true. This behaviour is summarized by:

$$if \vert v ( {t}_{1} ) \vert \geq \frac{{B}_{1}}{{K}_{01}} and sgn [ v ( {t}_{1} ) ] = 1 , \vert i ( {t}_{1} + τ ) \vert = + {B}_{1} , \\ whilst if \vert v ( {t}_{1} ) \vert \geq \frac{{B}_{2}}{{K}_{02}} and sgn [ v ( {t}_{1} ) ] = - 1 , \vert i ( {t}_{1} + τ ) \vert = - {B}_{2} . \qquad ( 17 )$$

In the special case that B₁=B₂=B and K₀₁=K₀₂=K₀, (17) becomes:

$$if \vert v ( {t}_{1} ) \vert \geq \frac{B}{{K}_{0}} and sgn [ v ( {t}_{1} ) ] = 1 , \vert i ( {t}_{1} + τ ) \vert = + B , \\ whilst if \vert v ( {t}_{1} ) \vert \geq \frac{B}{{K}_{0}} and sgn [ v ( {t}_{1} ) ] = - 1 , \vert i ( {t}_{1} + τ ) \vert = - B \qquad ( 18 )$$

and a symmetrical oN-LACE input signal ν(t₁) results in a symmetrical output function i(t₁+τ).

Between the quasi-linear and strongly non-linear signal regimes of the oN-LACE there is a ‘transitional’ signal region or ‘transition region’ (T). In this region, the behaviour of the non-linear amplitude control element is neither quasi-linear nor strongly non-linear. In the most preferred embodiment of the oN-LACE the transition region is negligibly wide.

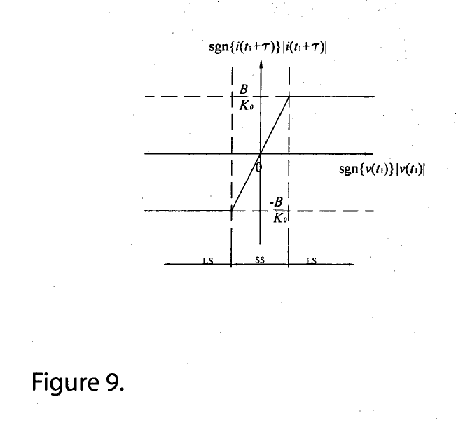

FIG. 9 illustrates the most preferred input-output characteristics of the oN-LACE for the case that: B₁=B₂=B and K₀₁=K₀₂=K₀ (18); there is no transitional (T) signal regime; the small-signal (SS) dynamic gain is independent of |ν(t₁)| and the large-signal (LS) dynamic gain is zero (16a).

Three key features of the oN-LACE are: Feature 1: a sharp transition between the quasi-linear (small-signal) and strongly non-linear (large-signal) regimes effected by the instantaneous signal magnitude |ν(t₁)| exceeding a pre-determined threshold the value of which may or may not be dependent on the polarity of the signal (c.f. (17), (18)); Feature 2: a narrow and preferably negligibly wide transitional signal regime; Feature 3: approximately instantaneous transition between quasi-linear and strongly non-linear regimes. Feature 3 is equivalent to the oN-LACE 70 having capacity to respond to changes in the amplitude (and frequency) of the instantaneous input signal ν(t₁) on a timescale typically significantly shorter than the characteristic signal period T i.e. the oN-LACE 70 has a certain amplitude temporal resolution Δτ<<T. Furthermore, with a particular implementation of the oN-LACE described in the context of the present invention, it may be arranged that the instantaneous amplitude of the oN-LACE output) i(t₁) corresponds approximately instantaneously to that of the input i.e. if desirable, it may be arranged that the time-constant τ defined in (12) is negligibly small. Alternatively and more generally, the oN-LACE 70 is designed such that a certain known time-delay τ (which may or may not be frequency dependent) exists between oN-LACE input and corresponding output; in such a system an oN-LACE input ν(t₁) gives rise to an output i(t₁+τ) with amplitude temporal resolution Δτ independent of τ. It is an important and particular feature of the present invention that the amplitude control achieved via the oN-LACE 70 is not of a slow-acting ‘averaging’ type. Moreover, changes in the centre frequency or dominant frequency component of the input signal ν(t₁) may be resolved on a time-scale comparable with the amplitude temporal resolution Δτ; i.e. the frequency content of a general output signal i(t₁+τ) corresponds to the instantaneous frequency content of the input ν(t₁).

The input-output signal characteristics of the oN-LACE 70 are now considered, for the special case that the input is a symmetrical, sinusoidal waveform with frequency ω₀ and period of oscillation T (9). Asymmetrical input signals are described subsequently. With reference to (11) and (12) and the analysis there, it is assumed that the oN-LACE input signal ν(t+τ₁) is a time-shifted, linearly amplified derivative of an electrical signal s(t): a monochromatic signal at the operating frequency of the RSD 10, ω₀. For clarity in this section all signals are referenced relative to time t defined by s(t):

s(t)=a sin ω₀t (19a)

ν(t+τ₁)=A sin ω₀t (19b)

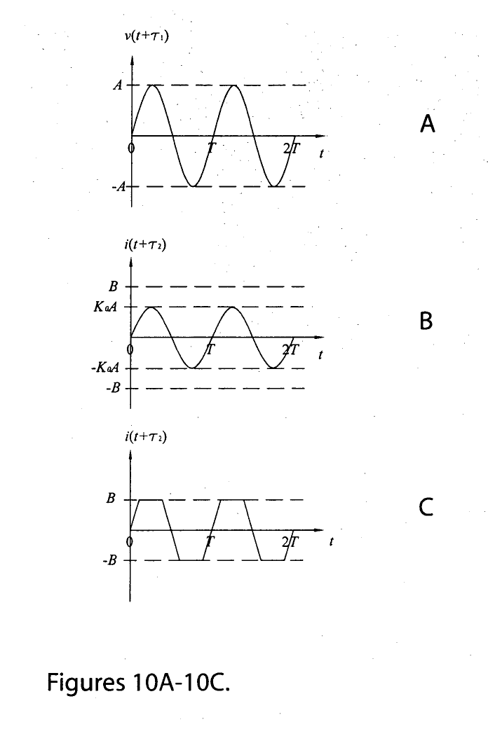

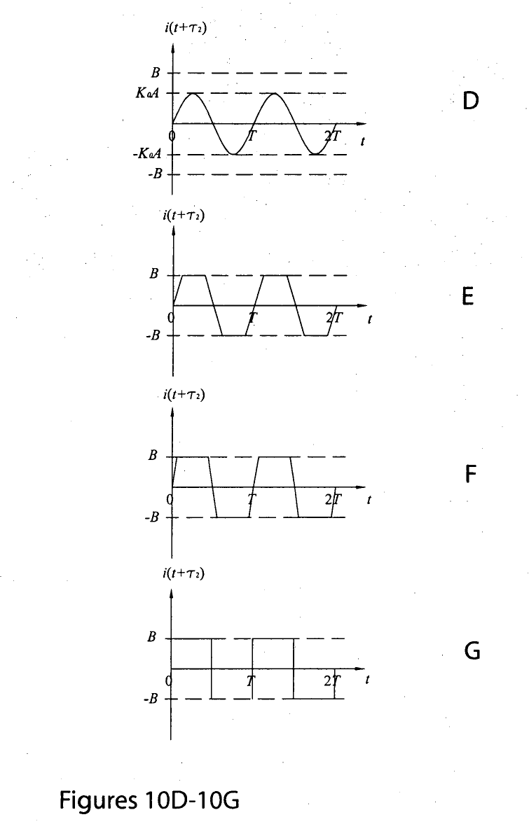

The oN-LACE input signal (19b) is depicted in FIG. 10A. In the analysis that follows, the particular case is considered that the positive and negative amplitude thresholds characteristic of the oN-LACE 70 have equal magnitude (i.e. (18) holds), that the small-signal regime is characterized by a certain constant dynamic gain K₀ independent of the polarity of the signal ν(t+τ₁), that the large-signal dynamic gain is zero and that there is no transitional signal regime.

In the quasi-linear amplification regime, the output signal from the oN-LACE 70 is given by a time-shifted, linearly amplified version of the input signal:

i(t+τ₂)=AK₀ sin ω₀t. (20)

FIG. 10B shows the output i(t+τ₂) of the non-linear amplitude control element for the case that for the entire period T of the signal ν(t+τ₁),

$$\vert v ( t + {t}_{1} ) \vert \leq \frac{B}{{K}_{0}} ,$$

i.e. the oN-LACE 70 operates continuously in the quasi-linear amplification regime.

FIG. 10C shows the output from the non-linear control element i(t^{τ}₂) for the case that during around half of the period of the input signal T,

$$\vert v ( t + {τ}_{1} ) \vert > \frac{B}{{K}_{0}} .$$

The function of the oN-LACE 70 is to amplify the received monochromatic energy signal ν(t+τ₁) at ω₀ (in general an amplified, time-shifted, phase compensated version of a raw electrical signal s(t)), and redistribute its RMS power over harmonics of the signal frequency ω₀. The Fourier series describing the oN-LACE input and output signals may be analysed to give an insight into how the distribution of power is affected by the amplitude A of the input signal ν(t+τ₁). In particular a Fourier representation of the output signal of the oN-LACE may be derived, which corresponds to a symmetrical sinusoidal input of general amplitude A assuming oN-LACE characteristics as described above.

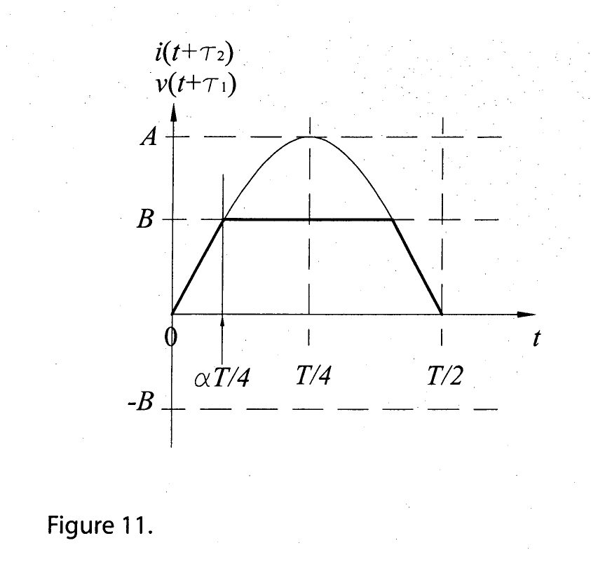

FIG. 11 shows a single positive half-cycle of ν(t+τ₁) and, superimposed (bold), a single positive-half cycle of a corresponding oN-LACE output i(t+τ₂). The limiting values of the oN-LACE output, ±B are indicated. It is assumed that the ratio A/B is such that for a fraction (1−α) of a quarter-cycle,

$$\vert v ( t + {τ}_{1} ) \vert \geq \frac{B}{{K}_{0}}$$

i.e. for the positive half-cycle

$$\vert v ( t + {τ}_{1} ) \vert \geq \frac{B}{{K}_{0}} for \frac{α T}{4} < t + {τ}_{1} \leq \frac{T}{4} ( 2 - α )$$

whilst for the negative half-cycle

$$- \vert v ( t + {τ}_{1} ) \vert \leq - \frac{B}{{K}_{0}} for \frac{T}{4} ( 2 + α ) < t + {τ}_{1} \leq \frac{T}{4} ( 4 - α ) .$$

The constant B and angle α are related by

$$α = \frac{2}{π} a sin ( \frac{B}{{AK}_{0}} ) . \qquad ( 21 )$$

For all possible values of AK₀, the periodicity and symmetry of i(t+τ₂) are preserved. Thus the Fourier series describing i(t+τ₂) is of the form

$$i ( t + {τ}_{2} ) = {b}_{1} sin {ω}_{0} ( t + {τ}_{2} ) + {\sum }_{3}^{∞} {b}_{n} sin n {ω}_{0} ( t + {τ}_{2} ) \\ n = 2 m + 1 for m = 1 , 2 , 3 , … \qquad ( 22 )$$

with coefficients

$$\begin{matrix}{b}_{1} = {AK}_{0} ( α - \frac{1}{π} sin ( πα ) ) + \frac{4 B}{π} cos ( \frac{π}{2} α ) , & ( 23 a ) \\ {b}_{n} = \frac{2 {AK}_{0}}{π} \{ \begin{matrix}\frac{1}{( 1 - n )} sin ( ( 1 - n ) \frac{π}{2} α ) - \\ \frac{1}{( 1 + n )} sin ( ( 1 + n ) \frac{π}{2} α )\end{matrix} \} + \frac{4 B}{n π} cos ( n \frac{π}{2} α ) & ( 23 b )\end{matrix}$$

For constant B and increasing AK₀, the fraction α decreases and i(t+τ₂) tends to a square wave with fundamental frequency component ω⁰. FIGS. 10D-G illustrate i(t+τ₂) for increasing A. FIG. 10G illustrates the waveform for the limiting case AK₀>>B, α→0. When the latter condition is fulfilled, the power in the signal i(t+τ₂) at the fundamental frequency ω⁰ is given by

$${P}_{0} = {( \frac{4 B}{π} )}^{2} . \qquad ( 24 )$$

Whilst the total power is the summation

$$P = {P}_{0} + {\sum }_{3}^{∞} {( \frac{4 B}{n π} )}^{2} n = 2 m + 1 for m = 1 , 2 , 3 , … \qquad ( 25 )$$

The summation (25) has a finite limit:

P=2B². (26)

Thus as AK₀→d where d>>B and α→0, the ratio P₀/P tends to a finite limit S₁:

$${S}_{i} = \frac{8}{{π}^{2}} = 0.8106 . \qquad ( 27 )$$

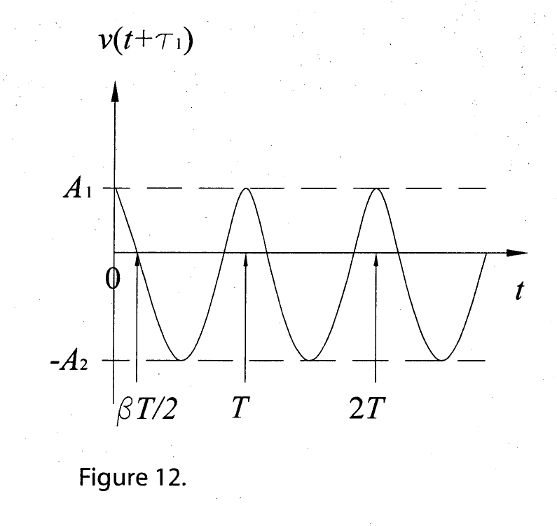

The Fourier analysis above may be extended to input waveforms of lower symmetry. For the purposes of illustration the simple asymmetric input function depicted in FIG. 12 may be considered, for which a single signal period T comprises a symmetrical positive cycle of duration βT and peak amplitude A₁ and a symmetrical negative cycle of duration (1−β)T of peak amplitude A₂ where β≠0.5. The Fourier representation of the asymmetric output signal i(t+τ₂) of the oN-LACE 70 may be derived in the large-signal regime for the particular case that the positive and negative amplitude thresholds characteristic of the oN-LACE 70 have magnitude B₁ and B₂ respectively, that the small-signal regime is characterized by a certain constant dynamic gain K₀ independent of the polarity of the input signal ν(t₁+τ₁), that the large-signal dynamic gain is zero and that there is no transitional signal regime.

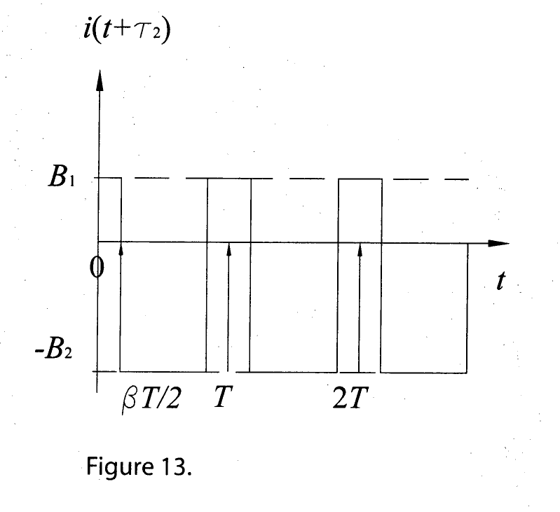

In the limit of large A₁K₀ and A₂K₀—i.e. in the large-signal regime—i(t+τ₂) tends to an asymmetric square wave with fundamental frequency component ω₀ as depicted in FIG. 13. Thus, the Fourier series describing i(t+τ₂) is of the form

$$i ( t + {τ}_{2} ) = {b}_{0} + {\sum }_{1}^{∞} {b}_{m} cos m {ω}_{0} ( t + {τ}_{2} ) m = 1 , 2 , 3 , … \qquad ( 28 )$$

with coefficients

$$\begin{matrix}{b}_{0} = β ( {B}_{1} + {B}_{2} ) - {B}_{2} , & ( 29 a ) \\ {b}_{m} = \frac{2 ( {B}_{1} + {B}_{2} )}{m π} sin ( m βπ ) . & ( 29 b )\end{matrix}$$

For the limiting case of large A₁K₀ and A₂K₀, the power in the signal i(t+τ₂) at the fundamental frequency ω₀ is given by

$${P}_{0} = {( \frac{2 ( {B}_{1} + {B}_{2} )}{π} )}^{2} {sin}^{2} ( βπ ) , \qquad ( 30 )$$

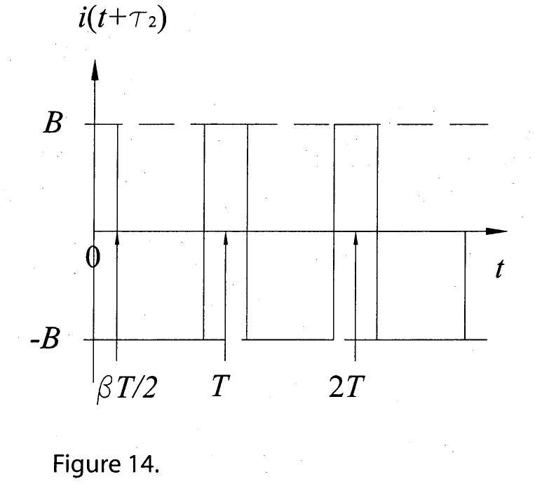

which for B₁=B₂=B (FIG. 14) reduces to

$${P}_{0} = {( \frac{4 B}{π} )}^{2} {sin}^{2} ( βπ ) . \qquad ( 31 )$$

To summarize the properties of the optimal non-linear amplitude control element that is preferably employed in the RSD 10 of embodiments of the present invention, it features three distinct signal regimes: a small-signal or quasi-linear regime (SS), a transitional signal regime (T) and a large-signal strongly non-linear regime (LS). In assessing the performance of a general non-linear amplitude control element 70 there are four key parameters to consider:

I. The small-signal dynamic gain at time t₁:

$${g}_{dSS} ( {t}_{1} ) = \frac{\partial i ( {t}_{1} + τ )}{\partial v ( {t}_{1} )} {\vert}_{SS}$$

where τ is a time delay characteristic of the input-out conversion in the N-LACE 70, which may or may not be frequency dependent.

II. The linearity of the small-signal quasi-linear regime.

III. The width of the transitional regime (T)—i.e. the range of input signal amplitudes for which the oN-LACE response would be described as transitional.

IV. The large-signal dynamic gain at time t₁:

$${g}_{dt . S} ( {t}_{1} ) = \frac{\partial i ( {t}_{1} + τ )}{\partial v ( {t}_{1} )} {\vert}_{LS}$$

where τ is as previously defined.

In the most preferred embodiment of the oN-LACE 70, the small-signal dynamic gain (I) takes a large constant value which may or may not be dependent on the polarity of the input signal (c.f. (17), (18)); the small-signal quasi-linear signal regime is approximately entirely linear (II), the transitional regime (T) (III) is so narrow as to be negligible, and the large-signal dynamic gain (IV) is zero.

FIG. 9 illustrates such an oN-LACE input-output characteristic for which the small-signal dynamic gain is K₀, independent of the polarity of the input signal ν(t) and the positive and negative amplitude thresholds have equal magnitude B. However, non-linear amplitude control elements with characteristics other than those shown in FIG. 9 are also contemplated.

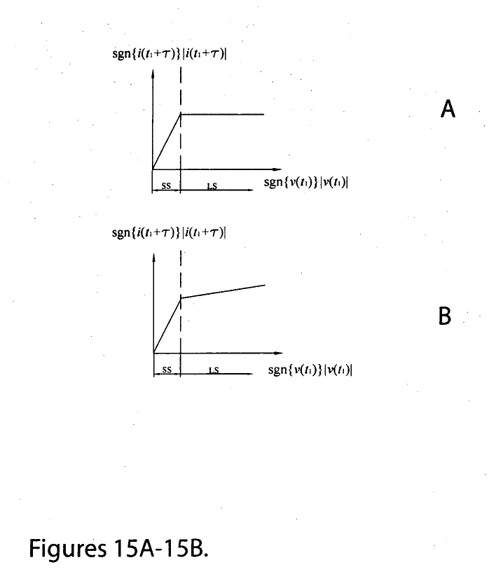

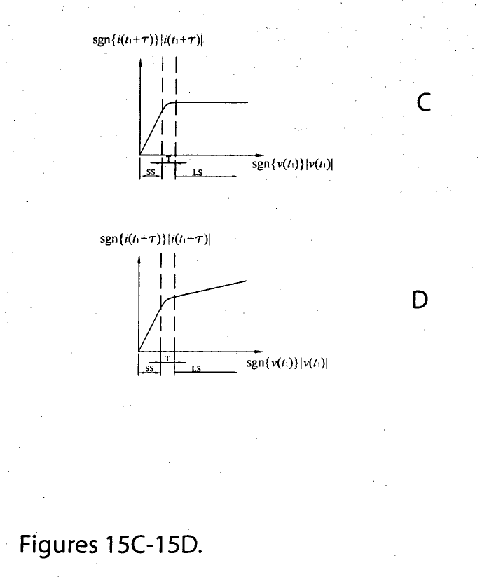

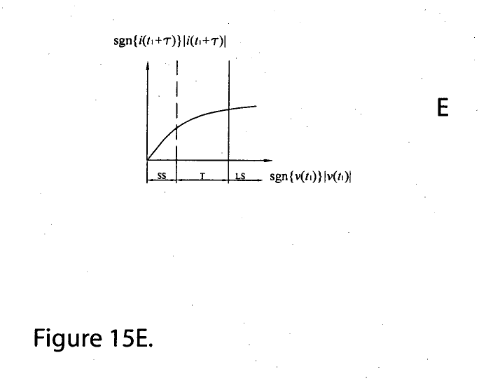

The family of non-linear amplitude control element input-output characteristics that fall within the oN-LACE definition are illustrated in FIGS. 15A-15D. FIGS. 15A-15D show only the oN-LACE 70 input-output characteristic for positive values of instantaneous input signal ν(t₁). Note that the relative polarities of the oN-LACE input and output signals are arbitrarily defined. In general, the input-output characteristics may be symmetric in ν(t₁), anti-symmetric in ν(t₁), or entirely asymmetric in ν(t₁). FIG. 15A shows the ‘ideal’ input-output characteristic—this is entirely equivalent to the section of the graph of FIG. 9 for positive ν(t₁)—the small-signal quasi-linear signal regime (SS) is approximately entirely linear, the transitional regime (T) is so narrow as to be negligible, and the large-signal dynamic gain (IV) is zero. FIG. 15B shows an oN-LACE input-output characteristic, less favourable than the ideal characteristic of FIG. 15A though still representing an advantageous arrangement of oN-LACE 70 suitable for use in the context of a RSD 10 embodying the present invention. Here, the small-signal quasi-linear signal regime (SS) is—as in the ideal case—approximately entirely linear, and the transitional regime (T) is so narrow as to be negligible. However, there is a non-zero large-signal dynamic gain. Although non-zero, this large-signal dynamic gain is very much smaller than the small-signal dynamic gain i.e. g_{dSS}>>g_{dLS}.

FIG. 15C shows another oN-LACE input-output characteristic, which is likewise less favourable than the ideal characteristic of FIG. 15A but nonetheless still advantageous in the context of an RSD device embodying the present invention. Here, the small-signal quasi-linear signal regime (SS) is—as in the ideal case—approximately entirely linear and the large-signal dynamic gain is approximately zero. However, there is a transitional regime (T) of finite width separating the small-signal quasi-linear (SS) and large-signal (LS) regimes. In this transitional region, the behaviour of the oN-LACE is neither quasi-linear nor strongly non-linear.

FIG. 15D shows yet another oN-LACE input-output characteristic, which is likewise less favourable than the ideal characteristic of FIG. 15A but nonetheless still advantageous in the context of an RSD device embodying the present invention. Here, the small-signal quasi-linear signal regime (SS) is—as in the ideal case—approximately entirely linear. However, there is a transitional regime (T) of finite width separating the small-signal quasi-linear (SS) and large-signal (LS) regimes. In this transitional region, the behaviour of the oN-LACE is neither quasi-linear nor strongly non-linear. Additionally, there is a non-zero large-signal dynamic gain. Although non-zero, this large-signal dynamic gain is very much smaller than the small-signal dynamic gain i.e. g_{dSS}>>g_{dLS}.

Other oN-LACE input-output characteristics are possible that are less favourable than the ideal characteristic of FIG. 15A but still provide advantages in the context of an RSD device embodying the present invention. For example, a slight non-linearity in the small-signal quasi-linear signal regime may be tolerated, as might a slight non-linearity in the large-signal regime. Combinations of slight non-idealities not explicitly described here are also permissible, for example: in a given oN-LACE characteristic there may be observed a slight non-linearity in the small-signal quasi-linear regime (SS), a narrow but non-negligible transitional region (T) and a small but non-zero large-signal dynamic gain g_{dLS} etc.

FIG. 15E shows a non-optimised N-LACE input-output characteristic which would not be preferred. Here, the small-signal (SS) regime differs considerably from the ideal, linear characteristic, the transitional regime (T) is wide such that one could not describe the transition from small-signal (SS) to large-signal (LS) regimes as ‘abrupt’ but might rather refer to it as ‘gradual’. The large-signal dynamic gain is also non-zero and the large-signal input-output response has some non-linearity.

In the most general sense, there are two different ways in which non-linear amplitude control functionality may be achieved. The first type of non-linear amplitude control incorporates a discrete active circuit element or an arrangement of discrete active circuit elements which provides a negative differential conductance or transconductance (i.e. gain) and a non-linearity. The non-linearity, and, in the majority of cases part or all of the gain, are each provided by a physical, non-linear process which is an inherent property of one or more of the circuit elements.

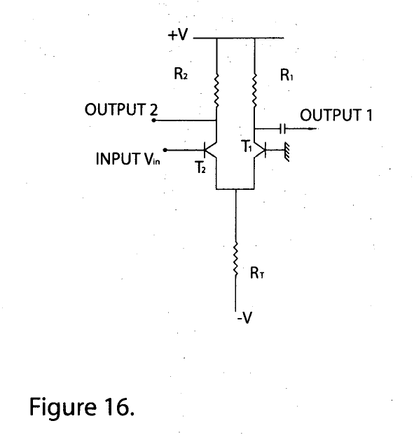

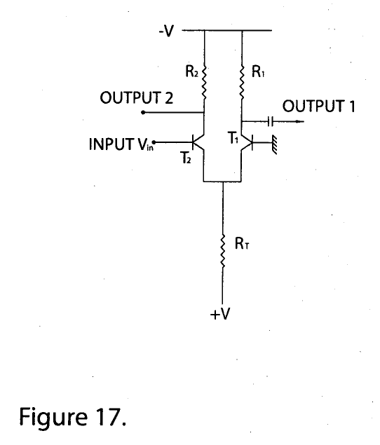

The functionality of the second type of non-linear amplitude controller is entirely equivalent to that of the first, but here, the non-linearity is provided not by an inherent physical non-linear process, but by deliberately arranging active elements so that the desired non-linear behaviour is promoted. One way of doing this is, for example, to exploit the gain saturation of an operational amplifier, or to use a transistor pair, as exemplified in FIGS. 16 and 17 (see below).

In both types of non-linear amplitude controller, the provision of gain and the provision of non-linearity may be considered as two independent functional requirements, which might accordingly be provided by two distinct functional blocks. In practice, the gain-non-linearity combination is often most readily achieved by exploiting the properties of a single collection of components. In any event, at least conceptually, the non-linearity may be considered as being superimposed on top of a linear gain characteristic, to create the desired set of input-output characteristics.

Considered in this way, the key function of the non-linearity is then to limit the maximum value of the gain (or the transconductance, or simply the output signal) of the overall amplitude regulator circuitry. Overall, the intention is that the combination of the “gain” functionality and the “non-linear” functionality provides a unit which delivers a significant gain for small signals, that has a constant magnitude output once the input exceeds a pre-determined threshold, as explained above.

FIGS. 16 and 17 show two simple exemplary circuits suitable for providing the desirable characteristics of an oN-LACE 70 as outlined above. Each circuit is of the second type of non-linear amplitude control described above, that is, each provides a circuit induced non-linearity provided by a pair of bipolar junction transistors. In the case of the arrangement of FIG. 16 the bipolar junction transistors are NPN, whereas in the case of FIG. 17 PNP transistors are employed.

Looking first at FIG. 16 a first embodiment of an oN-LACE is shown. The arrangement of FIG. 16 employs first and second NPN transistors T₁ and T₂, arranged as a long-tailed pair differential amplifier. The amplifier 60 (FIG. 2A) provides an input voltage Vᵢₙ to the base of transistor T₂. The base of transistor T₁ is grounded. The collector of transistor T₁ is connected to a positive voltage rail +V via a first resistor R₁, and a collector of the second transistor T₂ is connected to the same positive voltage rail via a second resistor R₂. The emitters of each transistor T₁, T₂ are connected in common to a negative voltage rail −V via a tail resistor R_{T}.

The collector of the first transistor T₁ is capacitively coupled to the delay-line sensor system 20. Thus the circuit of FIG. 16 provides an amplified and regulated version of the circuit input to the base of transistor T₂ to drive the delay-line sensor system 20. In addition, this current regulated output from the collector of the first transistor T₁ may be connected to the frequency counter 80 (FIG. 2A) to provide a frequency output.

The collector of the second transistor T₂ provides a second circuit output to the peak detector/demodulator 90 (see FIG. 2A again). This output from the collector of the second transistor T₂ is an AC signal at the frequency of the input signal Vᵢₙ with an amplitude proportional to that input voltage. This input level dependent signal, when demodulated by the demodulator 90, recovers a DC signal which is proportional to the input level. This DC signal may for example be employed to monitor changes in the quality factor (Q) of an oscillator resonance. More specific details of this use of the demodulator output are set out below, where some examples of particular implementations of the RSD 10 embodying the present invention are described.

FIG. 17 shows an alternative circuit arrangement to that of FIG. 16. The configuration is identical save that the transistors T₁ and T₂ are, in FIG. 17, PNP transistors, and the voltage rails are thus reversed.

In each case of the circuit arrangements of FIGS. 16 and 17, for small amplitude; of input, injecting a signal at the base of the second transistor T₂ results in a proportional current flow in the collector of the first transistor T₁. This is the linear regime of the oN-LACE and is provided via the small-signal “linear gain” regime of the transistor pair. Once the input reaches a certain threshold value, the first transistor T₁ is instantaneously driven “fully on”, and its collector current accordingly saturates at a predetermined value. This provides the “strongly non-linear” characteristic of the oN-LACE.

In each of the circuits of FIGS. 16 and 17, the collector current of the second transistor T₂ varies with the voltage amplitude of the input signal for all values of input. Demodulation of this signal by the demodulator 90 provides, therefore, a means to monitor the amplitude of the input to the circuit.

Having set out the principles underlying embodiments of the present invention, some examples of practical devices employing these principles will now be described.

Any delay-line sensor system may be reduced to an equivalent two-port electrical network (or arrangement of such networks). The voltage and current at any point along a delay-line sensor system 20 comprising at least one delay-line is conveniently described using transfer function matrices. Such transfer function matrices may be manipulated either by hand or by computer using a numerical technique in order to solve for the resonance and anti-resonance frequencies of a given delay-line sensor system 20.

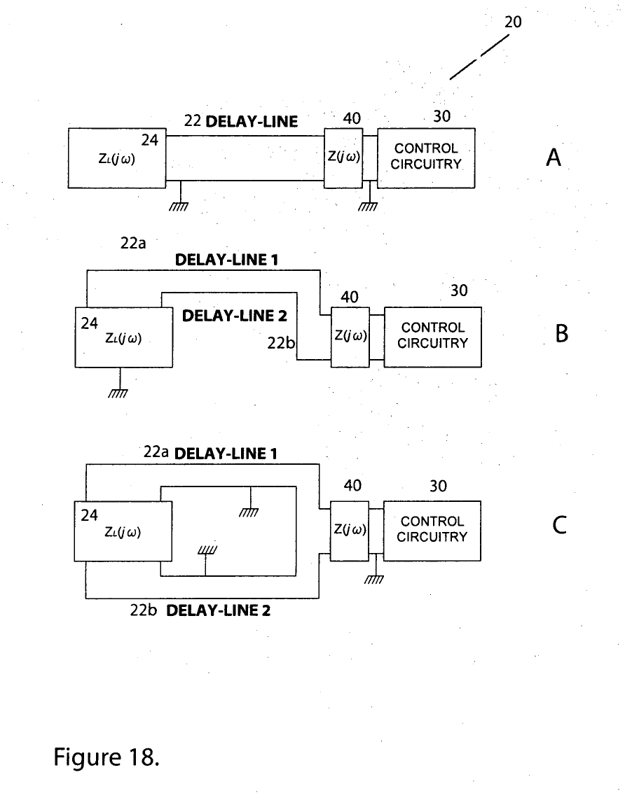

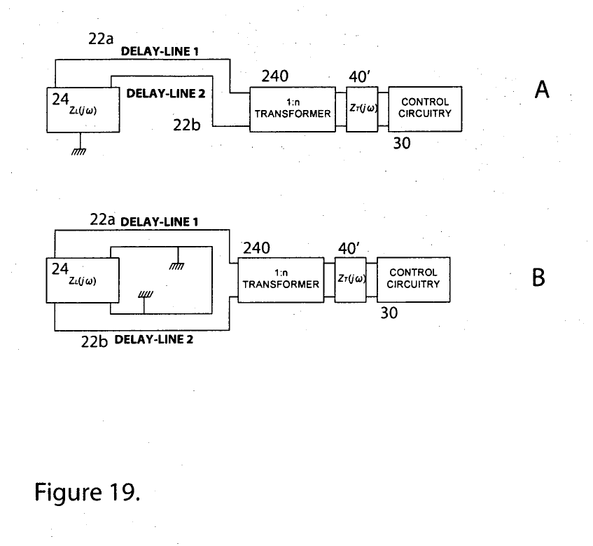

FIGS. 18 and 19 are block schematic diagrams of several example RSDs 10 realized in conjunction with a selection of simple delay-line systems 20. Such RSDs 10 may be realized in conjunction with any type or types of delay-line(s). FIG. 18A illustrates an arrangement incorporating a delay-line sensor system 20 as previously described: a single length of delay-line 22, terminated by an sensor 24 with impedance Z_{L}(jω) connected to the control circuitry 30 via a frequency selection impedance Z(jω) 40.

FIG. 18B shows a RSD 10 realization in which two delay-lines 22a, 22b are separately connected to the control circuitry 30 and a sensor 24 appears between an earth connection and the two signal lines. As with the arrangement of FIG. 18A, the control circuitry 30 is connected to the first and second delay-lines 22a, 22b via a frequency selection impedance Z(jω) 40.

FIG. 18C shows an alternative arrangement in which a sensor 24 appears in series with two delay-lines 22a, 22b separately connected to the control circuitry 30 via a frequency selection impedance Z(jω) 40.

FIG. 19A shows a further possible arrangement in which, rather than being directly connected to the control circuitry 30 via the frequency selection impedance Z(jω) 40 of FIG. 18B, the delay-line sensor system 20 is connected to the control circuitry 30 via a 1:n transformer 240. In this case, the frequency selection impedance Z_{T}(jω) 40′ is ‘transformed’ by the transformer 240 and thus the combination of the transformer 240 and the impedance Z_{T}(jω) 40′ present some impedance Z_{T}*(jω) which is the frequency selection impedance.

In the alternative system of FIG. 19B, the delay-line sensor system 20 of FIG. 18C is connected to the control circuitry 30 via a 1:n transformer 240. In this case, the frequency selection impedance Z_{T}(jω) 40′ is ‘transformed’ by the transformer 240 and thus the combination of the transformer and the impedance Z_{T}(jω) 40′ present some impedance Z_{T}*(jω) which is the frequency selection impedance.

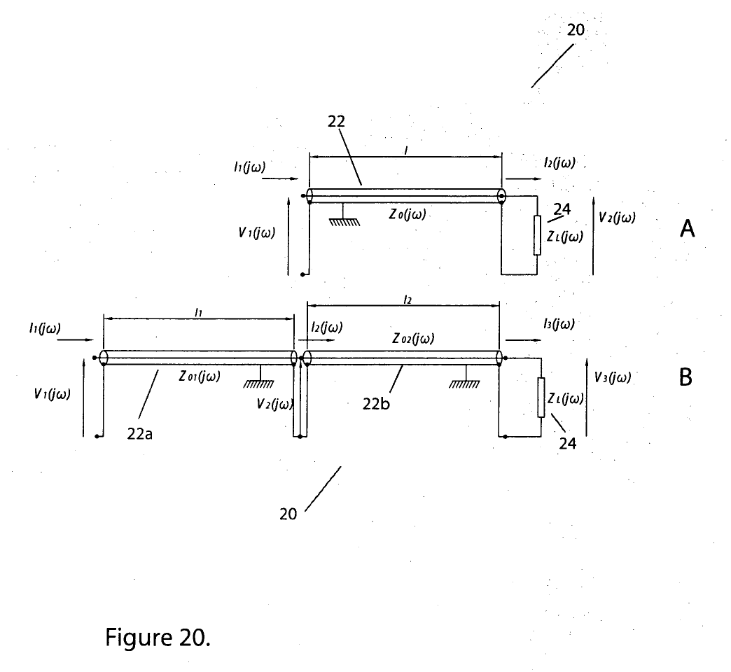

FIG. 20 illustrates delay-line sensor systems relevant to the RSD system of FIG. 18A. FIG. 20A shows a single length of delay-line 22, of length l, characteristic impedance Z₀(jω) connected to a sensor 24 with impedance Z_{L}(jω).

FIG. 20B shows two lengths of delay-line: delay-line 1 22a with length l₁, characteristic impedance Z₀₁(jω), propagation coefficient γ₁ and delay-line 2 22b, with length l₂, characteristic impedance Z₀₂(jω), propagation coefficient γ₂, connected to a sensor 24 with impedance Z_{L}(jω).

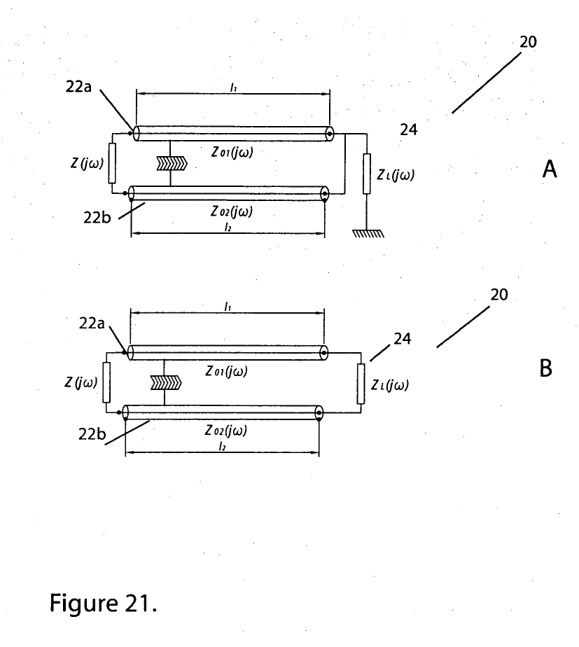

FIG. 21 illustrates particular delay-line sensor systems 20 in combination with frequency selection impedances relevant to the RSDs 10 of FIG. 18B and 18C. FIG. 21A shows two lengths of delay-line liner delay-line 1 22a with length l₁, characteristic impedance Z₀₁(jω), propagation coefficient γ₁ and delay-line 2 22b with length l₂, characteristic impedance Z₀₂(jω), propagation coefficient γ₂, connected to a shunt sensor 24 with impedance Z_{L}(jω). FIG. 21B shows two lengths of delay-line line—delay-line 1 22a with length l₁, characteristic impedance Z₀₁(jω), propagation coefficient γ₁ and delay-line 2 22b with length l₂, characteristic impedance Z₀₂(jω), propagation coefficient γ₂ connected in series with a sensor 24 with impedance Z_{L}(jω).

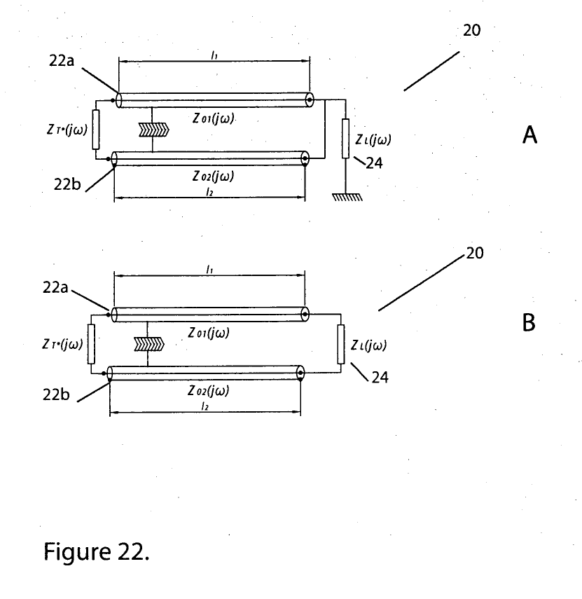

FIG. 22A illustrates a delay-line sensor system 20 in combination with a frequency selection impedance relevant to the RSD of FIG. 19A. The delay-line sensor system of FIG. 22A incorporates two lengths of delay-line line: delay-line 1 22a with length l₁, characteristic impedance Z⁰¹(jω), propagation coefficient γ₁ and delay-line 2 22b with length l₂, characteristic impedance Z₀₂(jω), propagation coefficient γ₂, connected to a shunt sensor 24 with impedance Z_{L}(jω). The delay-lines are connected to the control circuitry 30 via a frequency selection impedance Z_{T}*(jω) 40 which is the transformed impedance Z_{T}(jω) 40′.

FIG. 22B illustrates a delay-line sensor system 20 in combination with a frequency selection impedance relevant to the RSD of FIG. 19B. The delay-line sensor system of FIG. 22B incorporates two lengths of delay-line line: delay-line 1 22a with length l₁, characteristic impedance Z₀₁(jω), propagation coefficient γ₁ and delay-line 2 22b with length l₂, characteristic impedance Z₀₂(jω), propagation coefficient γ₂, connected in series with a sensor 24 with impedance Z_{L}(jω). The delay-lines 22a, 22b are connected to the control circuitry 30 via a frequency selection impedance Z_{T}*(jω) 40 which is the transformed impedance Z_{T}(jω) 40′.

A given implementation of the RSD 10 is designed to exploit the frequency response characteristics (e.g. those shown in FIG. 4) of a given delay-line sensor system 20.

Any combination of delay-line sensor system 20 and frequency selection impedance embodying the present invention may be described in terms of an effective impedance Zᵢₙ(jω) presented to the control circuitry 30.

Implementations of the RSD 10 divide into two categories: Type A RSDs are designed to operate the delay-line sensor system 20 at one of its characteristic resonance frequencies i.e. one of the frequencies at which the magnitude of the input impedance Zᵢₙ(jω) is minimum, and thus at a frequency at which there is observed a peak in the inverse magnitude response |Zᵢₙ(jω)|⁻¹ (FIGS. 4B and 4D for the particular example implementation discussed above). Type B RSDs are designed in such a way as to operate the delay-line sensor system 20 at a frequency not coincident with a characteristic resonance frequency of the delay-line sensor system 20. Type B RSDs may be advantageous over Type A RSDs if, for example a particular frequency of operation is desirable for optimal sensitivity of the sensor element 24 (see later) or for other practical reasons. In Type B RSDs it is generally arranged that though the operating frequency is not co-incident with a resonance frequency of the delay-line sensor system 20, it is proximal to a resonance frequency of the delay-line sensor system 20 rather than proximal to an anti-resonance frequency. Both Type A and Type B RSDs operate on the principle of a positive-feedback control system in which the frequency determining element comprises (Type A RSDs) or incorporates (Type B RSDs) the delay-line sensor system 20. The frequency selection impedance 40 Z(jω) may take the form of a simple combination of passive components or may be the effective impedance of some active circuit element.

Typically Zᵢₙ(jω) is characterised by not one but a multiplicity of resonance frequencies. Thus there is required in Type A realizations of the RSD 10 a means to select a ‘strongly-preferred mode’—i.e. to promote robust operation of the RSD 10 at a single particular resonance frequency. In Type B realizations of the RSD 10 there is furthermore required a means to promote operation of the RSD 10 at some single advantageous resonance frequency ω_{B}. In both Type A and Type B RSDs, modal selectivity may be achieved by several techniques. Two such techniques are discussed below.

Modal Selectivity Via Frequency Selection Impedance or Frequency Selection Impedance Stage Design

In this technique modal selectivity is achieved by combining an appropriately designed frequency selection impedance with a given delay-line sensor system 20.

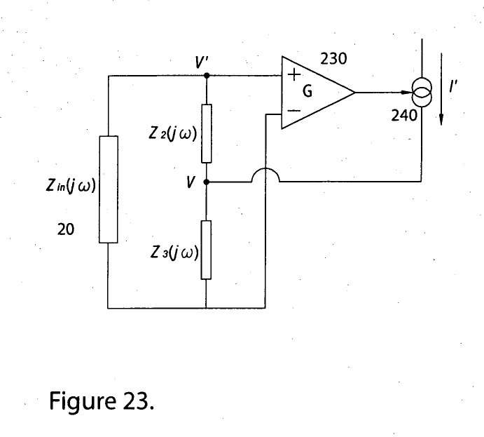

FIG. 23 shows a possible mode-selective feedback configuration in the context of the RSD 10. The delay-line sensor system 20 is represented by the equivalent frequency dependent impedance Zᵢₙ(jω). The frequency selection impedance stage which is the input stage to the control circuitry 30 comprises two purely imaginary frequency dependent impedances Z₂(jω) and Z₃(jω) in combination with an amplifier 230 and current source 240. The combination of the amplifier 230 and the two frequency dependent impedances together present a certain impedance to the delay-line sensor system 20. This impedance is the frequency selection impedance 40 Z(jω). The current source 240 provides an amplitude regulated current with some amplitude I′ as indicated in FIG. 23 and the combination of the current source 240 and amplifier 230 are equivalent to the driver 50, amplifier 60 and N-LACE components 70 shown in FIG. 2A. It can be shown that the conditions for self-oscillation of the schematic system of FIG. 23 may be met if the transconductance

$${g}_{m} = \frac{{I}^{′}}{V}$$

obeys

$${g}_{m} \geq \frac{r}{{Z}_{3} ( j ω ) ( {Z}_{3} ( jω ) + {Z}_{2} ( j ω ) )} . \qquad ( 32 )$$

where r is the loss equivalent resistance presented by Zᵢₙ(jω). Accordingly a figure of merit may be defined:

f(jω)=Z₃(jω)(Z₃(jω)+Z₂(jω)). (33)

By analogy with optical transitions in an homogenously broadened laser, if there are a number of possible RSD operating modes defined by the frequency response characteristics of Zᵢₙ(jω) which satisfy (29) the modes corresponding to the highest positive value of f(jω) will be favoured. Moreover, since the transconductance gₘ and r are necessarily positive quantities, certain modes may be excluded entirely by for example, selecting a combination of Z₂(jω) and Z₃(jω) such that f(jω) has a negative value at these frequencies.

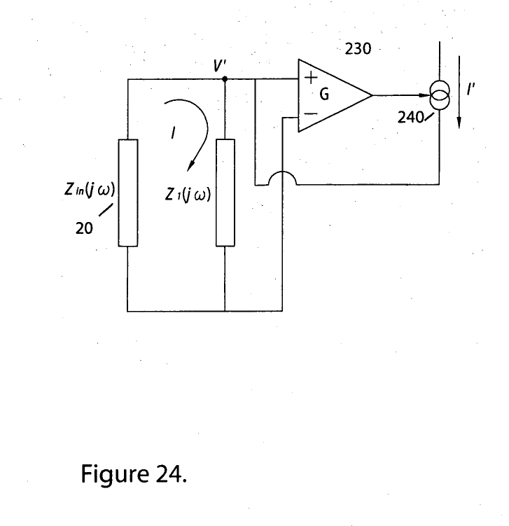

FIG. 24 shows a further example of a feedback scheme, again employing an amplifier 230 and a current source 240. In this case the condition on the transconductance

$${g}_{m} = \frac{{I}^{′}}{V}$$

for viable amplitude-stable self-oscillation is

$${g}_{m} \geq \frac{r}{{Z}_{1}^{2} ( j ω )} \qquad ( 34 )$$

and thus the figure of merit in this case is given by

f(jω)=Z₁²(jω). (35)

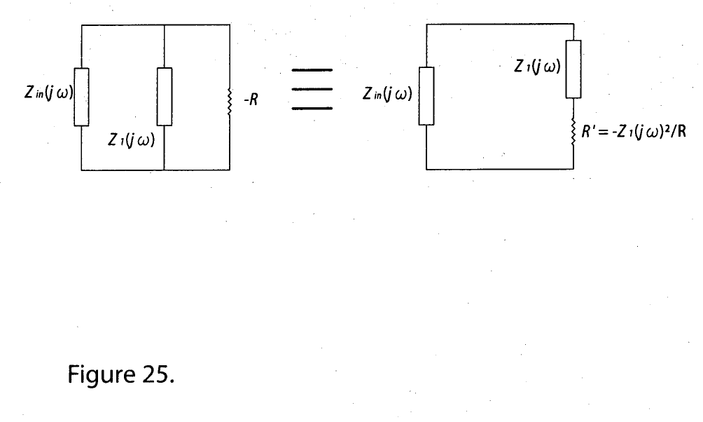

The system of FIG. 24 is equivalent to those shown in FIG. 25 where the combination of the imaginary component of the delay-line sensor system 20 impedance Zᵢₙ(jω) and the imaginary impedance Z₁(jω) define the operating mode of the RSD (i.e. this system represents a realization of a Type B RSD) and −R is a large negative resistance which compensates for the loss in the delay-line sensor system.

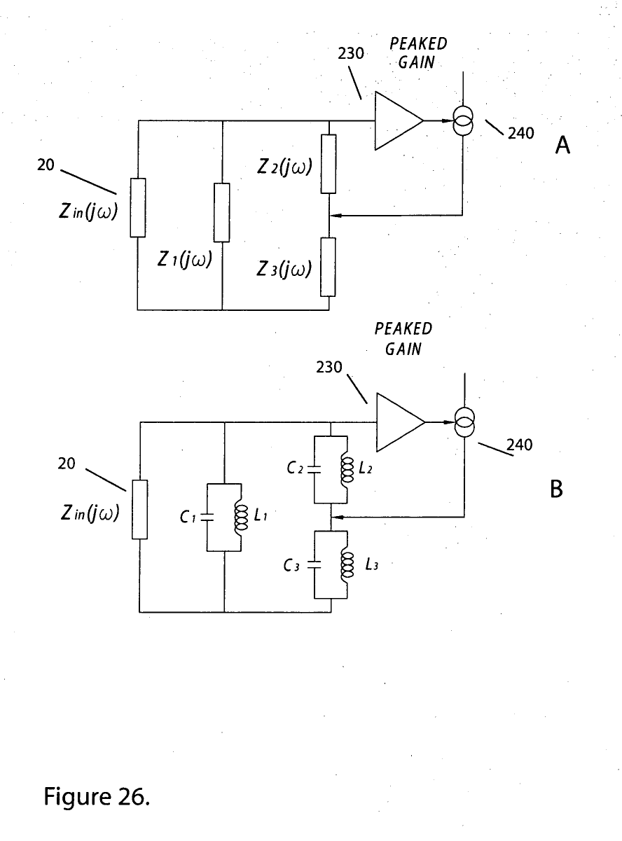

FIG. 26A shows a general mode-selective feedback configuration comprising in addition to the delay-line sensor system 20, four system variables the presence or value of which is determined by the particular requirements of the sensor instrumentation: three (generally imaginary) impedances Z₁(jω), Z₂(jω) and Z₃(jω) and the presence or otherwise of an amplifier peaked gain characteristic. Many possible variations of the general arrangement of FIG. 26A are possible, for example: the system of FIG. 23 is equivalent to that of FIG. 26A with Z₁(jω)→∞ and no peaked amplifier gain; the system of FIG. 24 is equivalent to that of FIG. 26A with Z₂(jω)=Z₃(jω)=0 and no peaked amplifier gain.

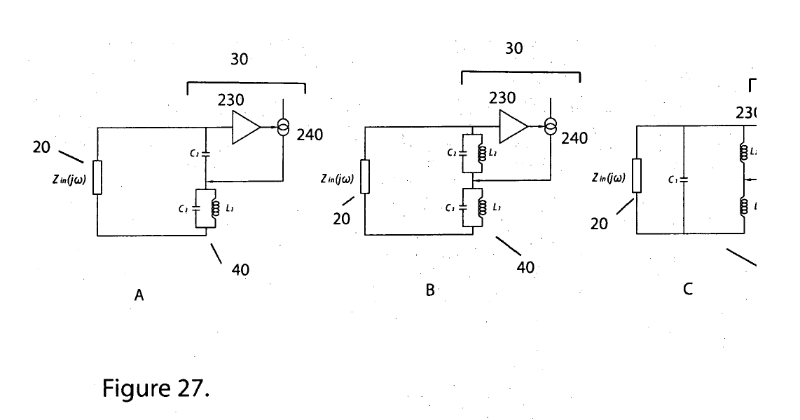

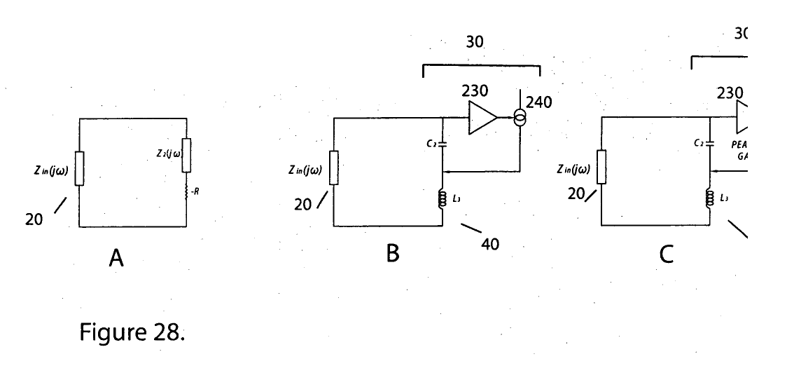

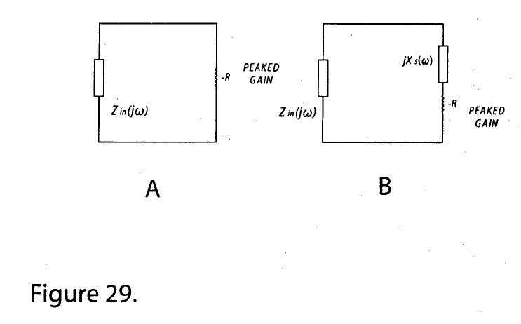

FIG. 26B shows a particular implementation of the general system of FIG. 26A in which the components Z₁(jω), Z₂(jω) and Z₃(jω) comprise combinations of capacitative and inductive elements. FIGS. 27-29 are schematic diagrams of possible variations of the arrangement of FIG. 26B. In each case, a delay-line sensor system 20 represented by an equivalent frequency dependent impedance Zᵢₙ(jω), a frequency selection impedance 40 and the control circuitry 30 are depicted. The schematics are for the purposes of illustration only and are not complete circuit diagrams. In the four arrangements of FIG. 27, the current source 240 provides an amplitude regulated current and the combination of the current source 240 and positive feedback amplifier 230 are equivalent to the amplifier 60, driver 50 and N-LACE 70 components shown in FIG. 2A. The combination of the configuration of the amplifier 230 and additional components provides the frequency selection impedance 40 Z(jω). In FIG. 28 four further possible arrangements are shown. In FIG. 28A an effective negative conductance −R is provided. FIG. 28B incorporates an amplifier 230 and current source 240 as in the arrangements of FIG. 27. In FIGS. 28C and 28D modal selectivity is at least partly achieved via a positive feedback amplifier stage 230 with a peaked gain. FIG. 29 illustrates two further arrangements. In FIG. 29A the peaked gain selects a delay-line sensor mode for which Zᵢₙ(jω)≈0 (i.e. a Type A RSD), whilst in the arrangement of FIG. 29B a Type B RSD system is realized, the operating frequency of which is such that ℑ{Zᵢₙ(jω)}=−X_{S}(ω).

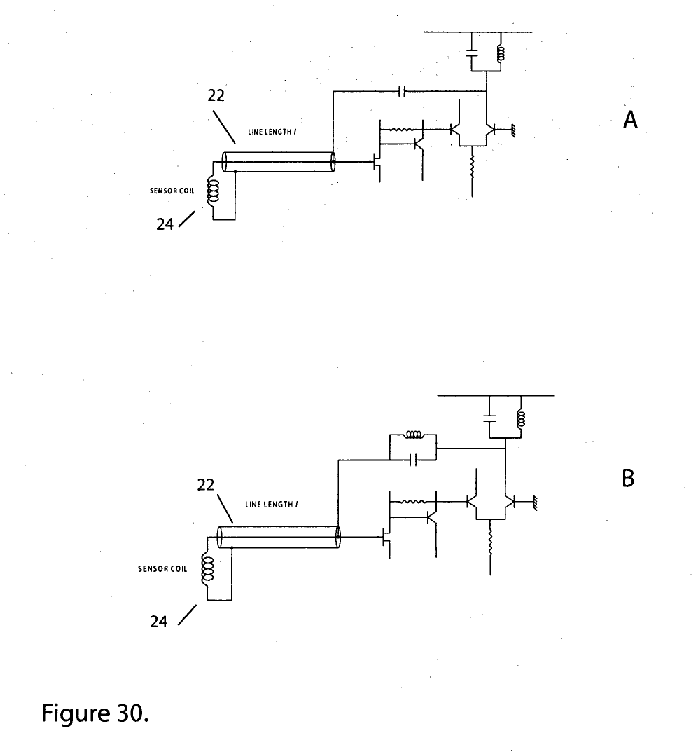

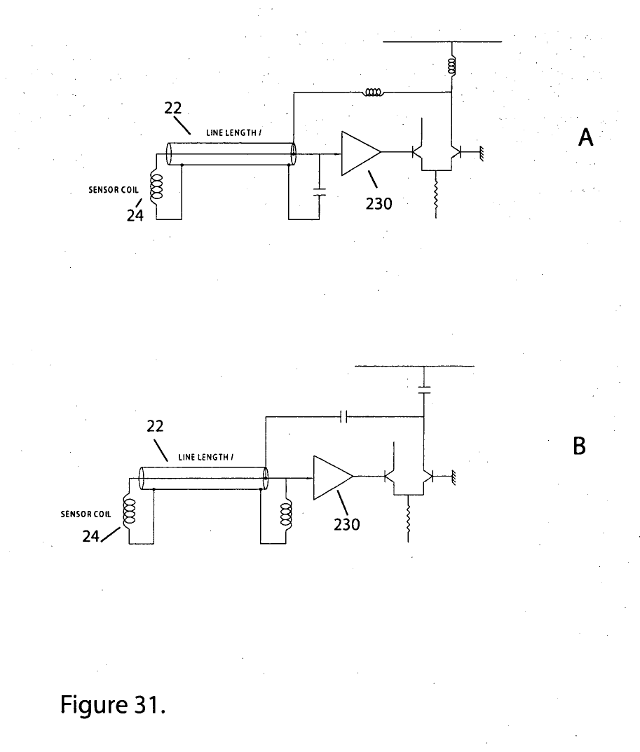

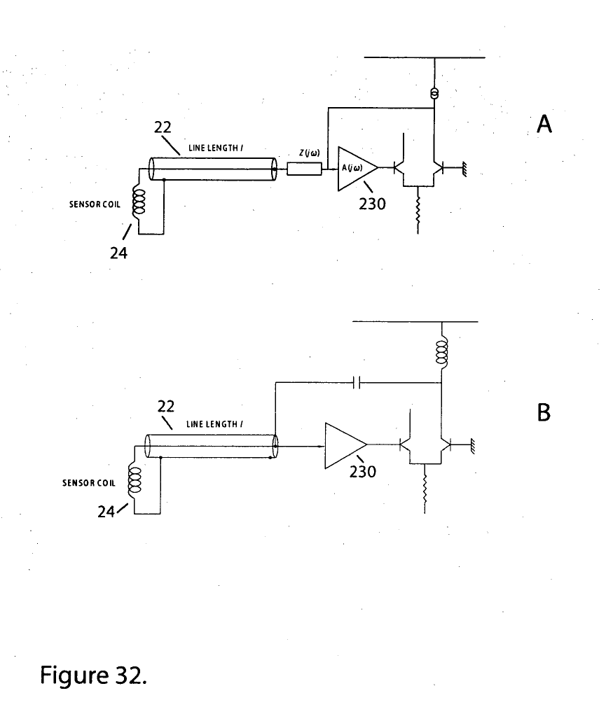

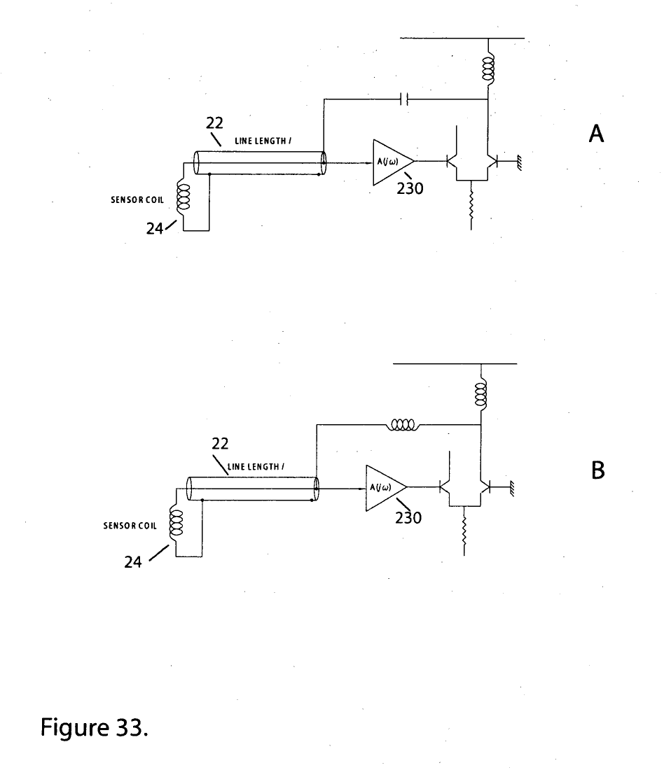

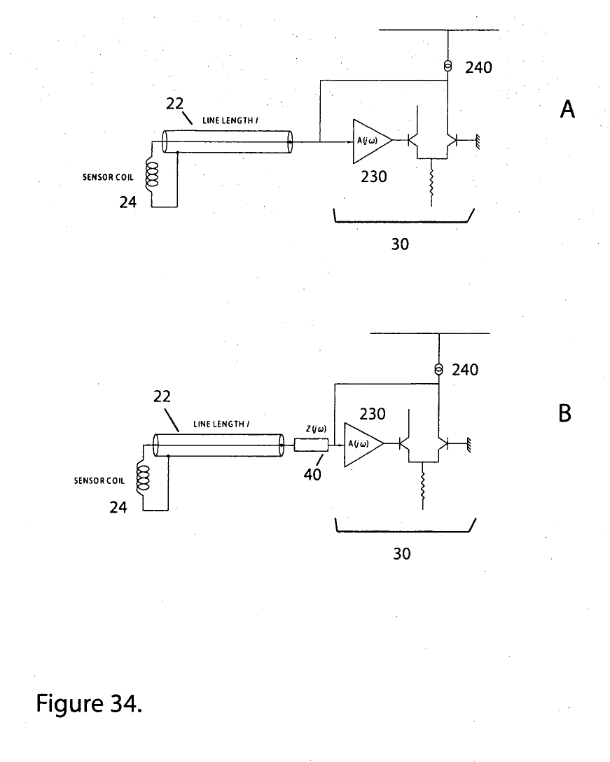

FIGS. 30-34 are schematic illustrations of how the arrangements of FIGS. 27-29 may be realized in practice. For the purposes of illustration, a delay-line sensor system comprising a single delay-line length l 22 terminated by a sensor coil 24 (which may for example have an equivalent circuit of the form shown in FIG. 3) is illustrated. The electrical systems shown in FIGS. 30-34 are not complete and are for illustrative purposes only. Many other arrangements are possible of course. FIGS. 30A and 30B correspond to the arrangements of FIGS. 27A and 27B respectively, FIGS. 31A and 31B to FIGS. 27C and 27D respectively, FIGS. 32A and 32B to FIGS. 28A and 28B respectively, FIGS. 33A and 33B to FIGS. 28C and 28D respectively, and FIGS. 34A and 34B to FIGS. 29A and 29B respectively.

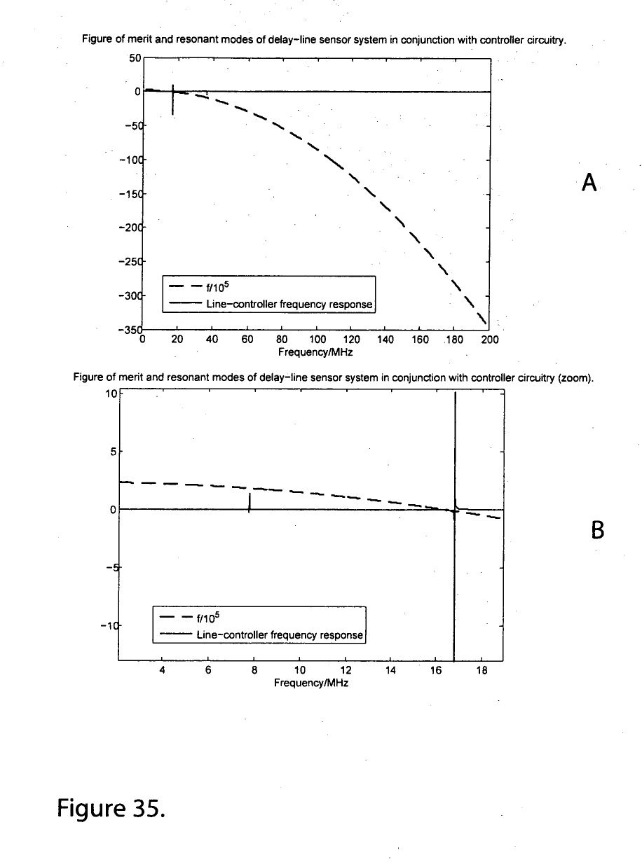

For the purposes of illustration, the characteristics of a particular implementation of the scheme of FIG. 23 with the parameters shown in Table 2 are shown in FIG. 35. The delay-line sensor system 20 is identical to that shown in FIG. 1A with a sensor impedance Z_{L}(jω) of the form shown in FIG. 3. This arrangement represents a Type B RSD. The solid line in each plot is of the combined delay-line sensor system-frequency selection impedance inverse frequency response between 0 and 200 MHz. The peaks in these solid lines correspond to resonant modes—i.e. potential operating modes of the RSD. The lowest visible peak, between 7 and 8 MHz (FIG. 35B) is the lowest resonant operating mode of the RSD. The dotted lines in each plot are of the figure of merit f(jω)—see equation (33). The magnified view of FIG. 35B shows the region of FIG. 35A between 3 and 18.5 MHz. With this particular arrangement FIG. 35B illustrates that the low frequency mode is selected (f(jω) positive) over the high frequency mode which is precluded since at this frequency (f(jω) takes a negative (infeasible) value.

TABLE 2

| Parameter | Symbol | Value |
|---|---|---|
| Delay-line length | l | 3 m |
| Delay-line characteristic impedance | Z₀ | 50 Ω |
| Delay-line phase velocity | νₚ | 2 × 10⁸ ms⁻¹ |
| Resistance of sensor coil | r | 0.5 Ω |
| Parasitic capacitance of sensor coil | C | 2.5 pF |
| Inductance of sensor coil | L | 1 μH |
| Impedance 2 | Z₂ (jω) | (10¹²/j20ω) Ω |
| Impedance 3 | Z₃ (jω) | j4.7ωμΩ |

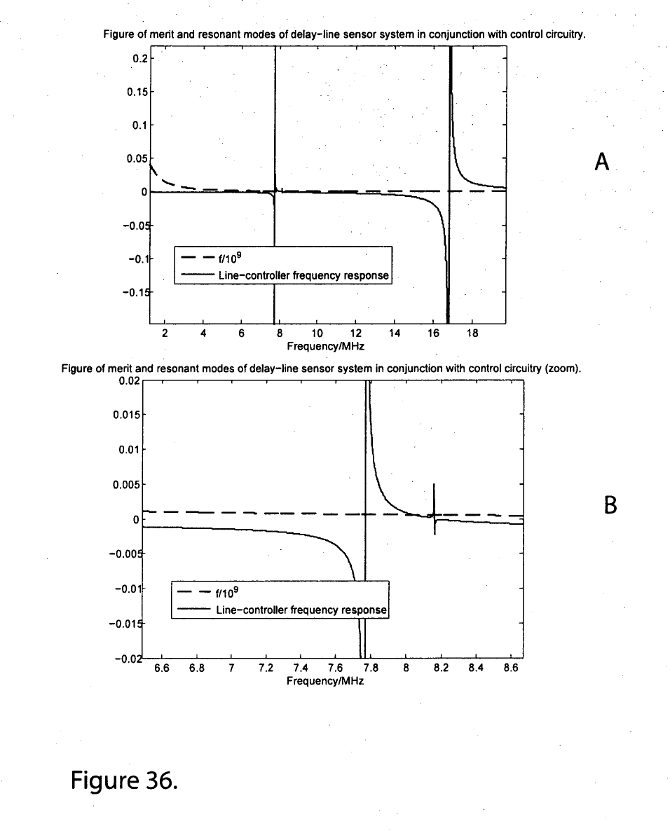

As a further illustration, the characteristics of a particular implementation of the scheme of FIG. 24 with the parameters shown in Table 3 are shown in FIG. 36. The delay-line sensor system is of the form shown in FIG. 1A again, with a sensor impedance Z_{L}(jω) of the form shown in FIG. 3. This system represents a Type B RSD. The solid lines in the plots are of the combined delay-line sensor system-frequency selection impedance inverse frequency response between 1.5 and 19 MHz. The peaks correspond to resonant modes—i.e. potential operating modes of the RSD. The lowest visible peak is between 7 and 8 MHz and represents the lowest resonant operating mode. The magnified view of FIG. 36B shows the region of FIG. 36A between 6.5 and 8.6 MHz. With this particular arrangement FIG. 36B illustrates that the low frequency mode is selected (f(jω) is positive and maximum) over all high frequency modes.

The dotted lines in FIGS. 36A and 36B represent the figure of merit defined by equation (32).

TABLE 3

| Parameter | Symbol | Value |
|---|---|---|
| Delay-line length | l | 3 m |
| Delay-line characteristic impedance | Z₀ | 50 Ω |
| Delay-line phase velocity | νₚ | 2 × 10⁸ ms⁻¹ |
| Resistance of sensor coil | r | 0.5 Ω |
| Parasitic capacitance of sensor coil | C | 2.5 pF |
| Inductance of sensor coil | L | 1 μH |
| Impedance 1 | Z₁ (jω) | (10¹²/j20ω + |
| | | j4.7 × 10⁻⁶ ω) Ω |

Modal Selectivity Via Variable Loop Gain

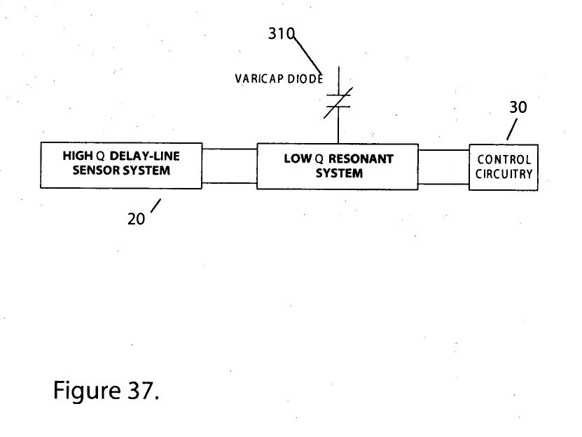

This alternative mode-stabilization technique is illustrated schematically in FIG. 37. Here, a frequency dependent gain is used to stabilize the desired RSD operating mode. The loop gain of the closed-loop controlled system is determined by a low Q resonant or anti-resonant system 300 which may for example have a frequency response featuring a single, broad resonant peak. The location of the broad resonant peak determines the mode selected. The location of the peak may be determined by a range of methods, including the incorporation of a varicap diode 310 as illustrated in FIG. 37. In the context of embodiments of the present invention, such a mode-stabilization method may be employed in conjunction with Type A or Type B RSDs. In the case of Type B RSDs, an additional frequency dependent imaginary impedance is introduced into the control loop such that the combination of this impedance with that of the delay-line sensor system 20 has one or more resonance frequencies, these resonance frequencies being potential RSD operating modes.

As explained above, the particular form of the delay-line sensor system 20, frequency selection impedance and control circuitry 30 may be designed in such a way as to optimize a given RSD 10 for a particular application. Particular properties of a variety of specific RSDs will accordingly now be described.

Design for Microphonic Noise Immunity

RSDs 10 incorporating a delay-line sensor system 20 featuring one or more delay-lines connected to the control circuitry 30 in a ‘loop’ type system (for example FIGS. 18B, 18C, 19A and 19B) have operating frequencies substantially determined by the characteristic length of the incorporated delay-line or lines and thus may be regarded as ‘time-of-flight’ type RSDs. Such time-of-flight arrangements feature excellent immunity to microphonic noise and many such time-of-flight type RSDs are possible. FIGS. 18B, 18C, 19A, 19B show time-of-flight type RSDs incorporating a sensor element 24 with some impedance Z_{L}(jω).

Design for Optimal Sensitivity and Stability

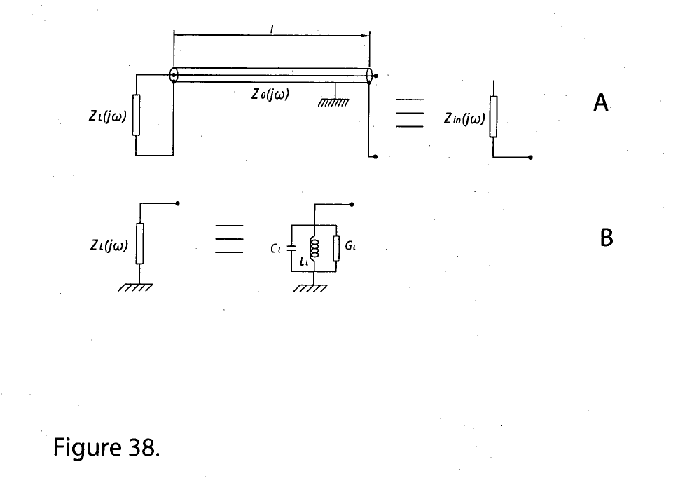

A RSD may be realized in conjunction with a given delay-line sensor system 20 such that the properties of the RSD are optimally sensitive and stable. The realization of an optimally sensitive RSD 10 (and the extent to which such an optimally sensitive and stable RSD 10 is viable within practical constraints) depends on the requirements and constraints presented by the delay-line sensor system 20 and the control circuitry 30. Here, for the purposes of illustration, the manner in which an optimal arrangement of delay-line 22 and sensor 24 may be determined for a delay-line sensor system 20 of the type presented in FIG. 38A—i.e. a length of transmission line 22 with characteristic impedance Z₀(jω), terminated by a sensor element 24 with some complex impedance) Z_{L}(jω)—is described. Further, the general case is considered in which the sensor element comprises three shunt components, a conductance G_{L}, capacitance C_{L} and inductance L_{L} (FIG. 38B), and an arrangement for optimal potential RSD sensitivity and stability to changes in the conductance G_{L} is then identified. Such changes in conductance might be brought about by additional loss in a real sensor system represented by such a combination of shunt components (for example a sensor coil). The effective quality factor Qₑ of the delay-line sensor system of FIG. 38A may be derived as:

$${Q}_{e} = 2 π \frac{Energy stored \text{/} cycle in delay - line + sensor element}{Energy dissipated \text{/} cycle in delay - line + sensor element} \qquad ( 36 )$$

For a given small change in the conductance of the sensor element δG_{L}, the biggest absolute increase in the energy dissipated in the delay-line sensor system 20 occurs for the case that the impedance Z_{L}(jω) of the sensor element 24 is matched to the characteristic impedance Z₀(jω) of the delay-line 22. Optimal sensitivity may thus be achieved by arranging that, at the operating frequency ω₁ of the RSD 10, the magnitude of the impedance of the sensor element 24 is equal to or approximately equal to the magnitude of the characteristic impedance of the line 22

|Z_{L}(jω₁)|=|Z₀(jω₁)|. (37)

The overall sensitivity of such an RSD system is further dependent on two related issues: the impedance relationship between the delay-line 22 and the sensor element 24 and the relationship between the effective quality factor Qₑ (equation 33) of the delay-line sensor system 20, the quality factor Q_{L} of the load (assuming that one can be defined—i.e. that the impedance of the sensor comprises an energy storage element and some dissipative element as is the case for the system of FIG. 38B) and the quality factor Q of the delay-line 22 in the absence of a load.

It has been established above that the impedance Zᵢₙ(jω) presented by a given delay-line sensor system 20 to a control circuitry 30 having a given circuit arrangement exhibits minima and maxima—i.e. there are featured both resonance and anti-resonance frequencies. In general, an RSD 10 is optimally stable if the delay-line sensor system 20 presents a small impedance to the control circuitry 30. Accordingly, if high sensitivity and high stability are required it is generally advantageous to arrange that the delay-line sensor system 20 is operated at or proximal to one of its resonance frequencies.

Design for Minimal Interaction in Networks of Instruments

In certain applications it is desirable to operate two or more sensor systems in close proximity with minimal interaction. Embodiments of the present invention offer a means by which two or more sensor instruments may be operated such that interaction between them is minimized or avoided.

When operated at or proximal to one of its characteristic resonance frequencies the delay-line sensor system 20 presents a small impedance to the control circuitry 30, whilst if operated at one of its anti-resonance frequencies, the impedance it presents is large or very large. By realizing two RSDs—RSD1 and RSD2—with independent delay-line sensor systems: respectively delay-line sensor systems 1 and 2, such that the operating frequency of RSD 1, ω₁ is co-incident with or proximal to a resonance frequency of delay-line sensor system 1 whilst being co-incident with or proximal to an anti-resonance frequency of delay-line sensor system 2 and vice-versa i.e. the operating frequency of RSD 2, ω₂ is co-incident with or proximal to a resonance frequency of delay-line sensor system 2 whilst being co-incident with or proximal to an anti-resonance frequency of delay-line sensor system 1, the two RSDs may be made substantially independent. Many possible methods of arranging this condition are possible and the technique may be extended to large networks of ‘switched-mode’ RSDs (see above). A simple illustrative example of such an arrangement is two RSDs both incorporating delay-line sensor systems of the type shown in FIG. 1A. Tables 4 and 5 specify the delay-line sensor systems 1 and 2 respectively. Table 6 indicates that if RSD 1 is operated at ω₁=81.3845 MHz whilst RSD 2 is operated at ω₂=100.0034 MHz, the impedance presented by the delay-line sensor system 1 to the control circuitry of RSD 1 at its operating frequency ω₁ is 5 orders of magnitude below the impedance presented by the delay-line system 2 to the control circuitry of RSD 2 at this frequency. Similarly, the impedance presented by the delay-line system 2 to the control circuitry 30 of RSD 2 at its operating frequency ω₂ is 8 orders of magnitude below the impedance presented by the delay-line system 1 to its control circuitry 30 at this frequency.

TABLE 4
Delay-line sensor system 1

| Parameter | Symbol | Value |
|---|---|---|
| Delay-line length | l₁ | 8 m |
| Delay-line characteristic impedance | Z₀₁ | 50 Ω |
| Delay-line phase velocity | νₚ₁ | 2 × 10⁸ ms⁻¹ |
| Resistance of sensor coil | r₁ | 0.5 Ω |
| Parasitic capacitance of sensor coil | C₁ | 2.5 pF |
| Inductance of sensor coil | L₁ | 1 μH |

TABLE 5
Delay-line sensor system 2

| Parameter | Symbol | Value |
|---|---|---|
| Delay-line length | l₂ | 8.5 m |
| Delay-line characteristic impedance | Z₀₂ | 50 Ω |
| Delay-line phase velocity | νₚ₂ | 2 × 10⁸ ms⁻¹ |
| Resistance of sensor coil | r₂ | 0.5 Ω |
| Parasitic capacitance of sensor coil | C₂ | 2.5 pF |
| Inductance of sensor coil | L₂ | 1 μH |

TABLE 6

| Parameter | Frequency/MHz | \|Zᵢₙ (jω)\|/Ω |
|---|---|---|
| Delay-line sensor system 1 | 100.0034 | 2.65 × 10⁵ |
| | 81.3845 | 0.005 |
| Delay-line sensor system 2 | 100.0034 | 0.007 |
| | 81.3845 | 166 |

An alternative method of interaction minimization in multiple RSD systems realized in embodiments of the present invention involves operating n corresponding delay-line sensor systems 20 at differing frequencies ωₙ and designing the control circuitry 30 such that for i=1 . . . n the i^{th} RSD 10 rejects all signals apart from those corresponding to n=i. This may be achieved by incorporating a filter element (which may for example take the form of a bandpass or notch filter) in each RSD 10 which filters the signal received from the delay-line sensor system 20 prior to amplitude regulation and feedback. A phase compensating element may also be included to compensate for unwanted signal phase-shifts brought about by the presence of such a filtering element.

Modes of Operation

RSDs embodying the present invention may be operated continuously or in a pulsed or ‘burst’ mode—i.e. for short periods of time whilst a measurement is made. In the case of such pulsed or bust-mode systems, the duration of time for which the RSD system is active must be sufficient for the RSD to commence and stabilize oscillation. Alternatively or additionally “switched mode” RSDs may be realized in which a single set of circuitry representing the control circuitry 30 is used in conjunction with multiple sensor elements 24 or delay-line sensor systems 20. The RSD 10 may be such that a single sensor element 24 or delay-line sensor system 20 is operative at any one time—i.e. one of several delay-line sensor systems 20 or one of several sensor elements 24 in conjunction with a given delay-line 22 or arrangement of delay-lines 22 are switched into operation electrically, mechanically, optically or otherwise at any one time Such switching may involve electrical changes at the control circuitry 30 and/or the delay-line 22 or delay-lines 22 and/or the sensor element or elements and/or the delay-line sensor systems 20. The operating frequencies particular to each delay-line sensor system 20 in such a RSD may be the same or different.

In a further embodiment of the RSD the frequency selection impedance or impedance stage may be locally or remotely controlled. Such local or remote control may be electrical, mechanical, optical, hydraulic etc. and may be such that the behaviour of the RSD 10—for example the operating frequency—is dependent on this control.

In a further implementation of the RSD, the operating mode may be controlled by an element or elements sensitive to some external stimulus such that the operating frequency of the RSD is determined by this stimulus and in response to certain changes in this stimulus a step-wise change in the operating frequency of the RSD is observed. The sensitive element or elements that determine the operating mode may be incorporated into the control circuitry 30 or may form part of the delay-line sensor system 20.

Delay-Lines Defined by Regions of Low Conductivity Media

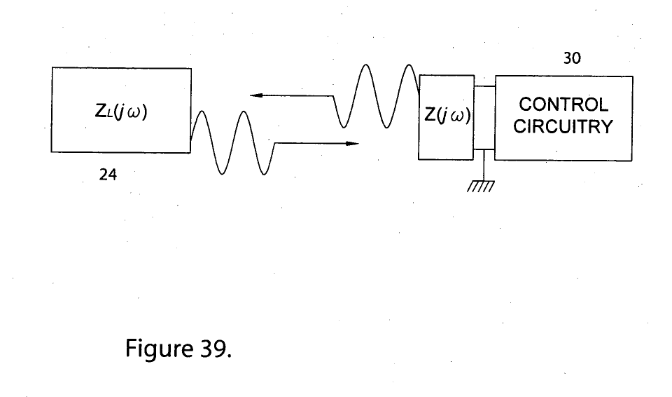

As established above, the RSDs that embody the present invention may be realized in conjunction with delay-line sensor systems 20 comprising or incorporating a delay-line or delay-lines defined by a region of free space or other low-conductivity transmission medium. This concept is illustrated schematically in the example system of FIG. 39. In such cases, transmitter and receiver elements (not shown) are provided to respectively supply and receive signals to and from the delay-line. The delay-line may be defined by a region of transmission medium or free space bounded by a certain boundary condition or boundary conditions, or as is the case in FIG. 39 the delay-line may be defined by the distance between the control circuitry 30 (and thus the transmit and receive system elements) and some other active or passive electrical sensor element Z_{L}(jω) 24.

Such systems may for example be used to realize sensitive distance measuring instruments (i.e. the distance between the control circuitry 30 and an active or passive electrical sensor element or elements may be determined from the characteristics of the resultant RSD 10), or to excite certain electrical sensor elements remotely and determine their characteristics (e.g. the electrical element Z_{L}(jω) 24 in FIG. 39 might represent a resonant electrical sensor element it is desirable to interrogate), or to excite certain electrical sensor elements remotely in order that they perform some electrical function. All possible implementations of the RSD embodying the present invention may be realized in conjunction with such ‘free space’ or low conductivity delay-lines.

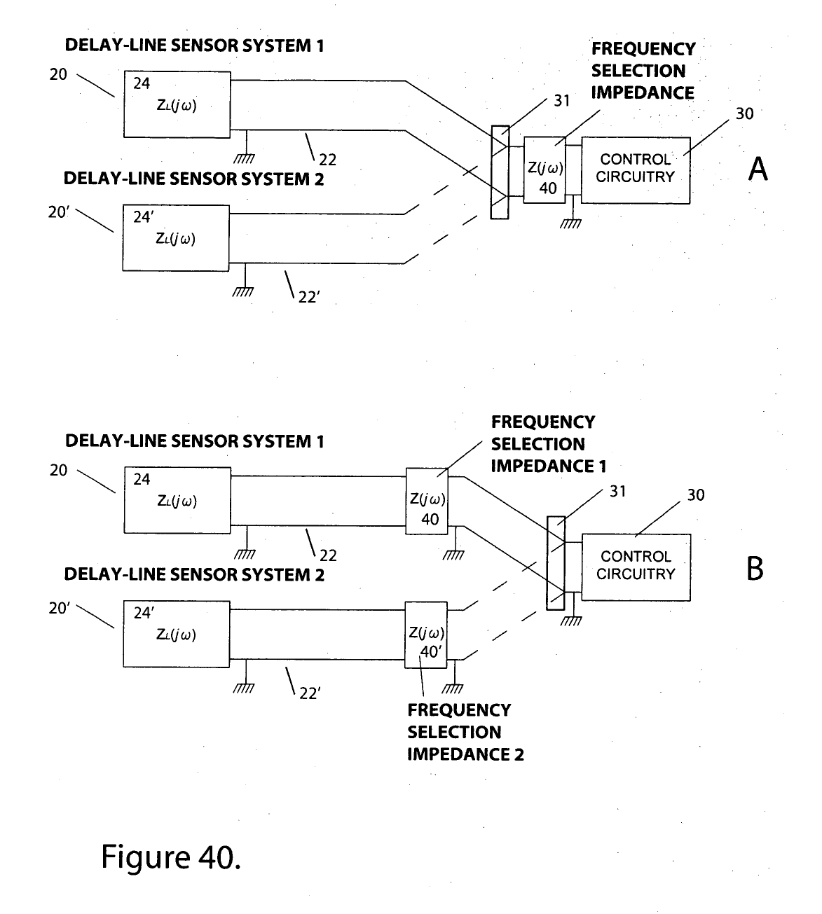

Although a specific embodiment of the present invention has been described, it is to be understood that various modifications and improvements could be contemplated by the skilled person. For example, although the foregoing description has set out a variety of different delay-line sensor systems, and frequency selection impedances, it will be understood that devices comprising multiple delay-line sensor systems and/or multiple frequency selection impedances could also be envisaged. FIGS. 40A and 40B show two such arrangements, schematically. In FIG. 40A, the control circuitry 30 is connected to the frequency selection impedance 40. A switch 31 then permits selective connection to either a first delay-line sensor system 20 (with first delay-line 22 and first sensor element 24) or a second delay-line sensor system 20′ (with second delay-line 22′ and second sensor element 24′). Of course, multiway switching between 3 or more delay-line sensor systems is equally possible.

In FIG. 40B, the control circuitry 30 is connected to a switch 31 which permits selective connection to a first “branch” having the first frequency selection impedance 40 and the first delay-line sensor system 20 (with first delay-line 22 and first sensor element 24) or to a second branch having a second frequency selection impedance 40′ and a second delay-line sensor system 20′ having a second delay-line 22′ and a second sensor element 24′). Again multiply switched devices with three or more frequency selection impedances and three or more respective delay-line sensor systems are feasible.

Particularly where the device comprises a single control circuitry 30 but multiple delay-line sensor systems 20, 20′ (optionally with multiple frequency selection impedances 40. 40′ as well), the sensor elements 24, 24′ may be, for example, coils. In that case, the coils might be arranged coaxially or side-by-side. The coils may also be of the same or substantially different diameters.

The device described herein finds many practical applications. One particular such application is in compressor or turbine blade monitoring in a jet or steam turbine engine. A brief description of certain such applications will now be set out. In this context—unless otherwise stated—the term ‘turbine blade’ is to be interpreted in the most general sense: i.e. any type of static, rotating or translating blade or blade-like object in piece of turbomachinery including for example, turbine, fan and compressor blades.

Parameters of the turbine blades such as linear or rotational speed, acceleration, profile, position, proximity, and/or temperature may be detected by an arrangement of the RSD 10, as well as blade jitter, timing, and axial shift (e.g. translation parallel to a turbine shaft around which the blades are radially disposed). Furthermore, if required, the sensitivity of the RSD to certain of these parameters may be arranged to be minimized (or compensated by mechanical or electrical design) whilst at the same time the sensitivity to other(s) of the parameters is maximised. For example: an RSD system may be arranged which detects and/or measures the proximity of a set of rotating turbine blade tips to a turbine casing (the blades being radially disposed around a turbine shaft) independently of any axial shift thereof (i.e. shift parallel to the blade shaft).

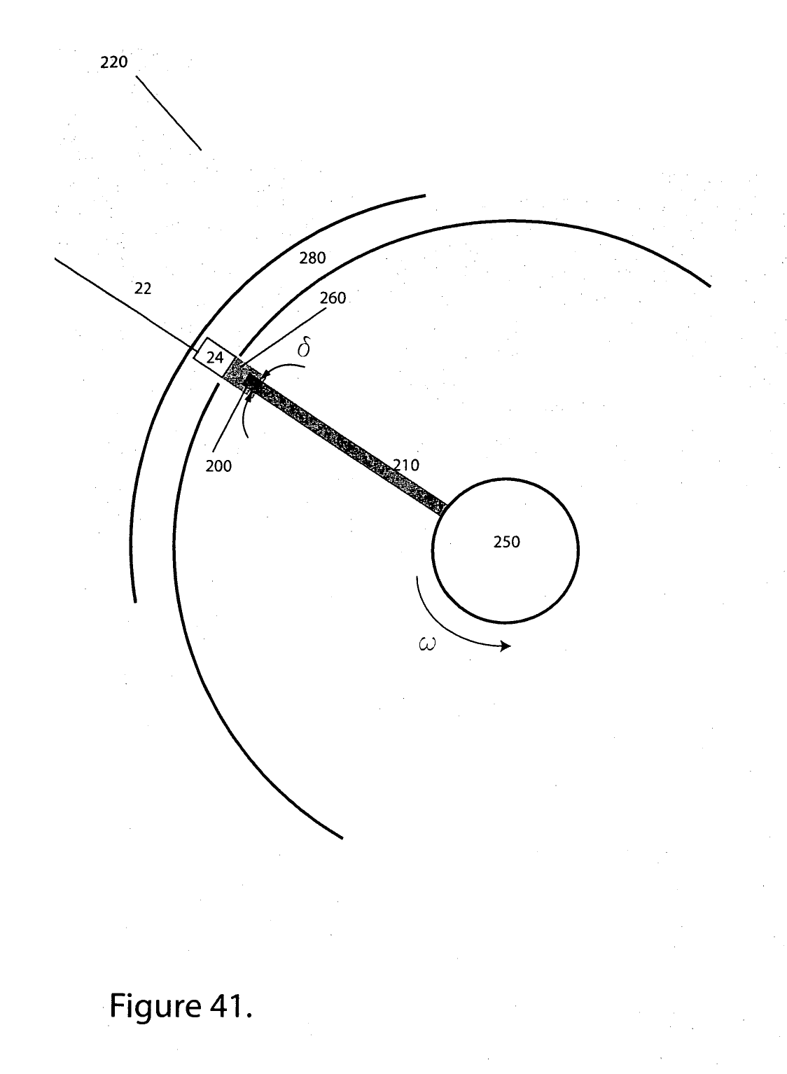

By way of example, FIG. 41 shows a typical highly schematic arrangement of a section of a rotational turbine stage of a turbine engine. Here, a first conductive object 200 is the tip of a turbine blade 210 of a turbine engine 220. A multiplicity of turbine blades 210 are arranged around a central turbine shaft component 250, one of which is shown. The sensor element 24 of the delay-line sensor system 20 of the RSD 10 is mounted in the turbine casing 280, In a particular embodiment, the sensor element 24 is a coil inset into the turbine casing but many other sensor elements and embodiments are possible. The sensor element has a certain sensitive volume 260 which is dependent on its geometry and design. In a particular implementation, the sensitive volume 260 is designed such that, when the axis of a particular turbine blade component 210 is parallel to the axis of the sensor element 24 (i.e. the orientation shown in FIG. 41), the sensitive volume 260 includes and is limited to a region of that particular turbine blade. In such an arrangement, particular blade tips pass through the sensitive volume 260 during a time interval

$$\frac{δ}{ω}$$

each full revolution of the shaft 250, where δ is the angular extent of each blade tip 200 in radians and ω the rotational speed of the shaft in radians per second). In accordance with the principles explained above, the control circuitry can be kept well away from the engine 220 by use of a delay-line 22, which may for example, have a length of several metres or several tens of metres. As each turbine blade enters the sensitive volume 260 of the sensor element 24 (which may for example, comprise a coil encapsulated in a temperature resistant material with low electrical loss) a signal is induced in the sensor element (which may for example, comprise a change in the real and/or imaginary component(s) of its electrical impedance). This signal brings about a corresponding change in the operating amplitude and/or frequency of the RSD which may then be processed in one of the manners described previously. As already outlined, such an arrangement allows detection of various parameters such as the relative speed of the turbine blade 210 and the casing 280, the proximity of the turbine blade tip 200 to the casing, and so forth. In an alternative arrangement, a second object 270 mounted on the turbine casing adjacent to the sensor element of the delay-line sensor system of the RSD 10 may be arranged such that its electrical properties are dependent on one or more properties of the first conductive object 200 (e.g. the proximity of the turbine blade tips) and that these electrical properties are interrogated by the sensor element, bringing about for example, a corresponding change in the real and/or imaginary component(s) of the sensor element's electrical impedance, and thus the amplitude and/or frequency of RSD operation.

Other applications can be envisaged in which the first conducting object 200 is formed from for example, a conductive element bonded to a turbine blade or a seal-ring feature thereof. Other applications can also be envisaged, wherein the second object 270 is for example moving or moveable and the sensor element 24 detects a parameter related to the relative properties (e.g. position) of the first 200 and second 270 objects.

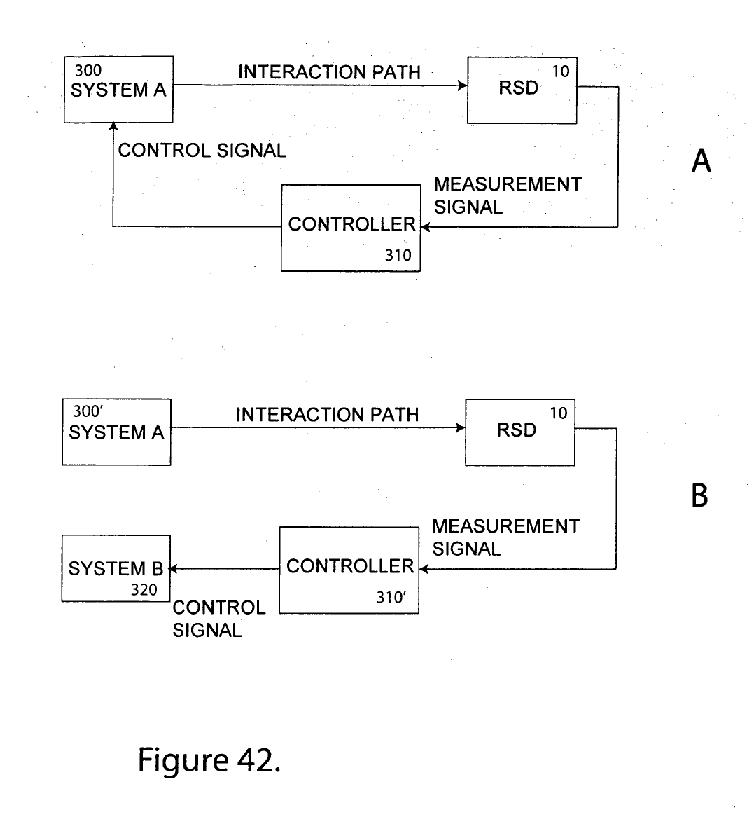

The RSD 10 may itself be used in a closed loop feedback arrangement. Alternative closed loop feedback arrangements are illustrated in block diagram form in FIGS. 42A and 42B respectively.

In FIG. 42A the RSD 10 as described above is connected in a first closed loop arrangement. A system A 300 provides a parameter to be measured/monitored/controlled, such as for example position or speed of rotation. That parameter is detected by the sensor element 24 (not shown explicitly in the block diagram of FIG. 41A) of the RSD 10. The RSD 10 then outputs a measurement signal, based upon the parameter detected by the sensor element 24, to a system controller 310. The controller may be any suitable controller configured in software or hardware. The system controller 310 then outputs a control signal to the System A 300 in order to control the System A 300 as a closed loop. The system controller may control either the same parameter, quantity or property as was detected by the sensor element, or a different one or a linked/associated one.

For example, if the proximity of a first component forming a part of the System A 300 is to be controlled relative to a second component, also forming part of the System A and upon which the sensor element 24 of the RSD is mounted, to a specified/predetermined distance, this may be set in the system controller 310. The proximity of the first component to the second component may then be continuously measured by the RSD 10, a measurement signal (related to the proximity of the first component) then being output by the RSD 10 to the system controller 310 which in turn sends an adjusting/controlling signal back to, for example a positioning system in the System A to adjust the proximity of the second component to the first component back to the target distance.

FIG. 42B shows an alternative closed loop arrangement to the closed loop configuration of FIG. 42A.

In FIG. 42B, a first system (System A) 300′ provides a parameter to be detected by the RSD 10. The sensor element 24 (again not shown in FIG. 42B) of the RSD detects the parameters of interest and the RSD 10 then outputs a measurement signal to a system controller 310′ in consequence. Unlike the closed loop of FIG. 42A, however, the system controller 310′ does not provide a control signal back to the first system (System A) 300′, but instead feeds a control signal forward to a second system (System B) 320. In other words, a parameter of a first system 310′ issued to control a parameter of a second, different system 320.

It is to be understood that the various features described herein are not mutually exclusive unless the context so requires. For example, the use of coaxial or side-by-side coils, of the same or different diameters, as the, or part of the sensor element(s) can equally be employed in the network of RSDs (that is, a system of multiple control circuitry, frequency selection impedances and delay-line sensor systems) as in the multiplexed/switched arrangements of FIGS. 40A and 40B.

1. A self-oscillating remote sensor device comprising:
a delay-line sensor system including at least one delay-line and at least one sensor element;
an oscillator control circuitry; and
a frequency selection impedance connecting the delay-line sensor system and the oscillator control circuitry and presenting an impedance to the delay-line sensor system;
wherein the oscillator control circuitry includes an amplifier, a non-linear amplitude control element (N-LACE) and a driver.

2. The self-oscillating remote sensor device of claim 1, wherein the non-linear amplitude control element (N-LACE) has an input and an output, and wherein the N-LACE is configured to provide an output signal at the N-LACE output which has a magnitude that has a negative second derivative with respect to an input signal supplied to the N-LACE input.

3. The self-oscillating remote sensor device of claim 1, wherein the N-LACE comprises an active device with a negative differential conductance.

4. The self-oscillating remote sensor device of claim 1, wherein the N-LACE comprises a differential amplifier arranged as a long tailed pair.

5. The self-oscillating remote sensor device of claim 4, wherein the differential amplifier comprises first and second bipolar junction transistors, wherein each of the first and second bipolar junction transistors comprises an emitter than is connected in common to a first potential via a tail load, and wherein each of the first and second bipolar junction transistors comprises a collector that is connected to second and third potentials via first and second loads respectively, the control circuitry amplifier output being supplied as an input to a base of the second transistor when a base of the first transistor is held at a fixed potential.

6. The self-oscillating remote sensor device of, claim 1, wherein the oscillator control circuitry further includes a signal acquisition/conditioning means.

7. The self-oscillating remote sensor device of claim 6, wherein the signal acquisition/conditioning means includes a frequency detector.

8. The self-oscillating remote sensor device of claim 6, wherein the signal acquisition/conditioning means further includes a peak detector or demodulator.

9. The self-oscillating remote sensor device of claim 1, wherein the at least one delay-line is formed from one or more of a length of coaxial transmission line, a waveguide, or a path in free space.

10. The self-oscillating remote sensor device of claim 1, wherein the frequency selection impedance includes a transformer.

11. The self-oscillating remote sensor device of claim 1, wherein the frequency selection impedance comprises first and second purely imaginary frequency dependent impedances and an amplifier input stage with a frequency dependent transfer function which together present a particular impedance to the delay-line sensor system.

12. The self-oscillating remote sensor device of claim 11, further comprising a third purely imaginary frequency dependent impedance in parallel with the first and second purely imaginary frequency dependent impedances.

13. The self-oscillating remote sensor device of claim 1, wherein the delay-line sensor system includes an electrically resonant element having a first quality factor Q1 and providing a frequency dependent gain, wherein the remaining components of the delay-line sensor system have a quality factor Q2 that is higher than the quality factor Q1 of the electrical element, and wherein the delay-line sensor system further includes a variable capacitor diode for adjusting the location of the resonant peak of the electrical element.

14. The self-oscillating remote sensor device of claim 1, further comprising one or more signal processing elements configured to stabilize the positive feedback oscillator in a single operating mode.

15. The self-oscillating remote sensor device of claim 14, wherein the one or more signal processing elements includes a means for varying an electrical frequency dependent transfer function.

16. The self-oscillating remote sensor device of claim 1, wherein the frequency selection impedance is configured to provide a frequency of oscillation of the remote sensor device substantially at a characteristic resonance frequency of the delay-line sensor system.

17. The self-oscillating remote sensor device of claim 1, wherein the frequency selection impedance is configured to provide a frequency of oscillation of the remote sensor device substantially at a characteristic resonance frequency of the combination of the delay-line sensor system and the frequency selection impedance.

18. The self-oscillating remote sensor device of claim 1, further comprising: at least one further delay-line sensor system including at least one delay-line and at least one sensor element; and
a switching means arranged between the frequency selection impedance and the plurality of delay-line sensor systems, for switching the oscillator control circuitry and frequency selection impedance between selected ones of that plurality of delay-line sensor systems.

19. The self-oscillating remote sensor device of claim 1, further comprising: at least one further delay-line sensor system including at least one delay-line and at least one sensor element; at least one further frequency selection impedance connecting a corresponding one of the further delay-line sensor systems and the oscillator control circuitry; and a switching means arranged between the oscillator control circuitry and the plurality of delay-line sensor systems and their corresponding plurality of frequency selection impedances, the switching means being arranged to permit the oscillator control circuitry to be selectively connected with one or other of the plurality of delay-line sensor systems and their corresponding frequency selection impedance.

20. A system comprising:
a self-oscillating remote sensor device comprising:
a delay-line sensor system including at least one delay-line and at least one sensor element;
an oscillator control circuitry; and
a frequency selection impedance connecting the delay-line sensor system and the oscillator control circuitry and presenting an impedance to the delay-line sensor system;
wherein the oscillator control circuitry includes an amplifier, a non-linear amplitude control element (N-LACE) and a driver; and
a first conductive object,
the at least one sensor element of the self-oscillating remote sensor device being arranged in proximity with the first conductive object so as to permit sensing of a parameter thereof.

21. A system comprising:
a self-oscillating remote sensor device comprising:
a delay-line sensor system including at least one delay-line and at least one sensor element;
an oscillator control circuitry; and
a frequency selection impedance connecting the delay-line sensor system and the oscillator control circuitry and presenting an impedance to the delay-line sensor system;
wherein the oscillator control circuitry includes an amplifier, a non-linear amplitude control element (N-LACE) and a driver, and
an arrangement to be sensed which includes a first conductive object and a second object;
wherein the at least one sensor element of the self-oscillating remote sensor device is arranged in proximity to the arrangement to be sensed so that a parameter of the first conductive object relative to the second object may be sensed.

22. The system of claim 20, wherein the first conductive object comprises or is mounted upon a first translatable or rotatable mechanical component of a mechanical system.

23. The system of claim 21, wherein the second object comprises or is mounted upon a second moveable or fixed component of a mechanical system.

24. The system of claim 22, wherein the first rotatable mechanical component comprises a part of a turbine, fan, or compressor blade in a turbine engine.

25. The system of claim 23, wherein the second moveable or fixed mechanical component comprises a part of a casing of a turbine engine.

26. The system of claim 20, wherein the parameter to be sensed is selected from the list comprising speed, acceleration, component profile, jitter, timing, proximity, position and temperature.

27. The system of claim 20, wherein the at least one sensor element includes at least one coil.

28. The self-oscillating remote sensor device of claim 18, wherein the sensor elements of the plurality of delay-line sensor systems each include at least one coil.

29. The self-oscillating remote sensor device of claim 28, wherein the at least one coil in the first delay-line sensor system is arranged coaxially or side by side with a coil of the at least one coil in the further delay-line sensor system.

30. The remote sensor device of claim 28, wherein the coils have different diameters.

31. A closed loop control arrangement comprising:
a remote sensor device comprising:
a delay-line sensor system including at least one delay-line and at least one sensor element;
an oscillator control circuitry; and
a frequency selection impedance connecting the delay-line sensor system and the oscillator control circuitry and presenting an impedance to the delay-line sensor system;
wherein the oscillator control circuitry includes an amplifier, a non-linear amplitude control element (N-LACE) and a driver;
a system controller; and
a system;
wherein the remote sensor device is arranged to output remote sensor device (RSD) output signal to the system controller based upon at least one of a property, parameter or quantity of the system measured by the sensor element of the delay-line sensor system, and
wherein the system controller is configured to provide a feedback control signal, to the system based upon the RSD output signal so as to control or modify the or a related property, parameter and/or quantity of the system.

32. A closed loop control arrangement comprising:
a first system,
a second system,
a system controller, and
a remote sensor device comprising:
a delay-line sensor system including at least one delay-line and at least one sensor element;
an oscillator control circuitry; and
a frequency selection impedance connecting the delay-line sensor system and the oscillator control circuitry and presenting an impedance to the delay-line sensor system;
wherein the oscillator control circuitry includes an amplifier, a non-linear amplitude control element (N-LACE) and a driver;
wherein the remote sensor device is arranged to output a remote sensor device (RSD) output signal to the system controller based upon at least one of a first property, parameter or quantity of the first system measured or detected by the sensor element of the delay-line sensor system, and wherein the system controller is configured to provide a control signal to the second system based upon the RSD output signal so as to control or modify at least one of a second property, parameter or quantity of the second system.

33. The arrangement of claim 32, wherein the at least one of the first parameter, property or quantity of the first system that is measured or detected by the sensor element is the same as the at least one of the second parameter property or quantity of the second system to be controlled.

34. The arrangement of claim 32, wherein the at least one of the first parameter, property or quantity of the first system that is measured or detected by the sensor element is different to the at least one of the second parameter property or quantity of the second system to be controlled.

35. A method of tracking a resonant mode in a remote sensor device, comprising:
exciting a resonant mode of the remote sensor device;
causing or allowing the resonance frequency of the resonant mode to change over time; and
tracking the resonant mode as it changes over time, by configuring the oscillator control circuitry and frequency selection impedance to supply a unity gain and an overall control-loop phase shift of 360.n degrees (where n is an integer>=0) only over the range of frequencies which the resonant mode changes over time.

36. A method of switching between resonant modes in a remote sensor device comprising:
exciting a first resonant mode of the remote sensor device; and
modifying the electrical impedance of the frequency selection impedance so as to promote operation of the remote sensor device at a second resonance frequency different to the first.

37. A method of switching between resonant modes in a remote sensor device comprising:
exciting a first resonant mode; and
modifying an electrical impedance of a delay-line sensor system so as to promote operation of the remote sensor device at a second resonance frequency distinct from the first.

38. A network of remote sensor devices (RSDs) comprising:
a first RSD having a first delay-line sensor system, in combination with a second RSD having a second delay-line sensor system different than the first delay-line sensor system,
wherein the first delay-line sensor system has a length that is different than a length of the second delay-line sensor systems so the operating frequency of the first RSD is co-incident with or proximal to a resonance frequency of the first delay-line sensor system while being co-incident with or proximal to an anti-resonance frequency of the second delay-line sensor system while the operating frequency of the second RSD is co-incident with or proximal to a resonance frequency of the second delay-line sensor system while being co-incident with or proximal to an anti-resonance frequency of the first delay-line sensor system.

39. (canceled)
